(19) United States
(12) Patent Application Publication
(10) Pub. No.: US 2024/0276808 A1
(43) Pub. Date: Aug. 15, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Fei FANG, Beijing (CN); Ke LIU, Beijing (CN); Ling SHI, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/562,885

(22) PCT Filed: Nov. 24, 2021
(86) PCT No.: PCT/CN2021/132892

§ 371 Date: Nov. 21, 2023

(30) Foreign Application Priority Data
May 21, 2021 (CN) 202110558588.2

(51) Int. Cl. H10K 59/131; H10K 59/121

(52) U.S. Cl. CPC H10K 59/131; H10K 59/1213; H10K 59/1216

(57) ABSTRACT

A display panel includes a display region and a peripheral region surrounding the display region; a binding region is provided on one side of the peripheral region; the display region comprises a first display region and a second display region which are adjacent to each other; and the light transmittance of the second display region is greater than that of the first display region. The display panel comprises a plurality of pixel driving circuits, and data leads used for loading data voltages to the pixel driving circuits; and in the second display region, the capacitance values of storage capacitors of the pixel driving circuits sequentially connected to a same data lead are gradually changed.

### CROSS REFERENCE

This disclosure claims priority to Chinese patent application No. 202110558588.2, titled “Display Panel and Display Device” and filed May 21, 2021, the entire content of which is incorporated herein by reference.

### TECHNICAL FIELD

This disclosure relates to the field of display technologies, and in particular, to a display panel and a display device.

### BACKGROUND

FDC (full-screen display camera) may be implemented in two manners, that is, built-in pixel circuit manner and externally-provided pixel circuit manner. When the pixel circuit is built in, the display quality inside the FDC area is poor.

It should be noted that the information disclosed in the above background section is only for enhancing the understanding the background of this disclosure, and therefore may include information that does not constitute the prior art known to those of ordinary skill in the art.

### SUMMARY

This disclosure is directed to overcome the shortcomings of the above-mentioned related art by providing a display panel and a display device, so as to improve the display quality.

According to a first aspect of this disclosure, a display panel is provided and includes a display region and a peripheral region surrounding the display region; where a binding region is provided on a side of the peripheral region; the display region includes a first display region and a second display region adjacent to each other; a light transmittance of the second display region is greater than a light transmittance of the first display region;
the display panel further includes a plurality of pixel driving circuits and data leads for loading data voltages to the pixel driving circuits; and
in the second display region, capacitance values change gradually in storage capacitors of respective ones of the pixel driving circuits sequentially connected to a same one of the data leads.

In some embodiments of this disclosure, along a direction away from the binding region, the capacitance values decrease gradually in the storage capacitors of the respective ones of the pixel driving circuits located in the second display region and connected to the same one of the data leads.

In some embodiments of this disclosure, the display panel further includes scanning leads for loading scanning signals to the pixel driving circuits; and in the second display region, capacitance values are the same in storage capacitors of respective ones of the pixel driving circuits sequentially connected to a same one of the scanning leads.

In some embodiments of this disclosure, a storage capacitor of the pixel driving circuit includes multi-layer electrode plates sequentially stacked on a side of a base substrate of the display panel;
odd-numbered layers of the electrode plates are electrically connected to each other, and even-numbered layers of the electrode plates are electrically connected to each other;
two adjacent layers of the electrode plates overlap and are electrically insulated with each other; a total overlapping area of the electrode plates of the storage capacitor is equal to a sum of overlapping areas between any two adjacent layers of the electrode plates; and
along a direction away from the binding area, the total overlapping areas of the electrode plates decrease gradually in the storage capacitors of the respective ones of the pixel driving circuits located in the second display region and connected to the same one of the data leads.

In some embodiments of this disclosure, in the second display region, a number of electrode plates of the storage capacitor of the pixel driving circuit is four.

In some embodiments of this disclosure, an overlapping area between a first electrode plate and a second electrode plate is a first overlapping area; an overlapping area between the second electrode plate and a third electrode plate is a second overlapping area; an overlapping area between the third electrode plate and a fourth electrode plate is a third overlapping area; and
along the direction away from the binding region, at least one of the first overlapping areas, the second overlapping areas and the third overlapping areas decrease gradually in the storage capacitors of the respective ones of the pixel driving circuits located in the second display region and connected to the same one of the data leads.

In some embodiments of this disclosure, the pixel driving circuit includes a driving transistor for generating a driving current; a first electrode plate of the storage capacitor is reused as a gate of the driving transistor; and
along the direction away from the binding region, areas of the first electrode plates remain unchanged in the storage capacitors of the respective ones of the pixel driving circuits located in the second display region and connected to the same one of the data leads.

In some embodiments of this disclosure, the display panel further includes pixel driving regions for providing the pixel driving circuits; and
an area of a pixel driving region in the second display region is smaller than an area of a pixel driving region in the first display region.

In some embodiments of this disclosure, the display panel further includes signal lines for connecting adjacent ones of the pixel driving circuits; and
in the second display region, a material of a part of the signal lines outside the pixel driving region is a transparent conductive material.

In some embodiments of this disclosure, the display panel further includes a base substrate, a semiconductor layer, a first gate layer, a second gate layer, a first source-drain metal layer, a second source-drain metal layer and a pixel electrode layer sequentially stacked; the display panel further includes a transparent wiring layer located between any two adjacent ones of the semiconductor layer, the first gate layer, the second gate layer, the first source-drain metal layer, the second source-drain metal layer and the pixel electrode layer; and
in the second display region, a part of the lines outside the pixel driving region is located in the transparent wiring layer.

According to a second aspect of this disclosure, a display panel is provided and includes a base substrate, a driving circuit layer, and a pixel layer stacked in sequence; where,
the pixel layer is provided with sub-pixels, the driving circuit layer is provided with pixel driving circuits for driving the sub-pixels, and the driving circuit layer includes a thin film transistor and a storage capacitor; and
the storage capacitor includes multi-layer electrode plates stacked in sequence; odd-numbered layers of the electrode plates are electrically connected to each other, and even-numbered layers of the electrode plates are electrically connected to each other; two adjacent layers of the electrode plates overlap and are electrically insulated with each other; and at least part of the storage capacitors includes more than two layers of the electrode plates.

In some embodiments of this disclosure, at least part of the storage capacitors includes four layers of the electrode plates.

In some embodiments of this disclosure, at least part of the storage capacitors includes two layers of the electrode plates.

In some embodiments of this disclosure, the display panel further includes a display region and a peripheral region surrounding the display region; where the display region includes a first display region and a second display region adjacent to each other; a light transmittance of the second display region is greater than a light transmittance of the first display region;
the first display region is provided with a first pixel driving circuit, and the second display region is provided with a second pixel driving circuit.

In some embodiments of this disclosure, a storage capacitor of the first pixel driving circuit includes two layers of electrode plates.

In some embodiments of this disclosure, a storage capacitor of the second pixel driving circuit includes four layers of electrode plates.

In some embodiments of this disclosure, the display panel further includes a first pixel driving region for providing the first pixel driving circuit and a second pixel driving region for providing the second pixel driving circuit;
where an area of the second pixel driving region is smaller than an area of the first pixel driving region.

In some embodiments of this disclosure, the display panel further includes signal lines for connecting adjacent ones of the pixel driving circuits; and in the second display region, a material of a part of the signal lines outside the second pixel driving region is a transparent conductive material.

In some embodiments of this disclosure, the display panel further includes a base substrate, a semiconductor layer, a first gate layer, a second gate layer, a first source-drain metal layer, a second source-drain metal layer and a pixel electrode layer sequentially stacked; where the display panel further includes a transparent wiring layer located between any two adjacent ones of the semiconductor layer, the first gate layer, the second gate layer, the first source-drain metal layer, the second source-drain metal layer and the pixel electrode layer; and
in the second display region, a part of the signal lines outside the second pixel driving region is located in the transparent wiring layer.

In some embodiments of this disclosure, the driving circuit layer includes a semiconductor layer, a first gate insulating layer, a first gate layer, a second gate insulating layer, a second gate layer, an interlayer dielectric layer, a first source-drain metal layer, a first planarization layer, a second source-drain metal layer and a second planarization layer sequentially stacked on a side of the base substrate; the driving circuit layer further includes a transparent wiring layer located between any two adjacent ones of the semiconductor layer, the first gate layer, the second gate layer, the first source-drain metal layer, the second source-drain metal layer and the pixel electrode layer; and
the multi-layer electrode plates of the storage capacitor are respectively located in multiple ones of the first gate layer, the second gate layer, the first source-drain metal layer, the second source-drain metal layer and the transparent wiring layer.

In some embodiments of this disclosure, the driving circuit layer includes a semiconductor layer, a first gate insulating layer, a first gate layer, a second gate insulating layer, a second gate layer, an interlayer dielectric layer, a first source-drain metal layer, a first planarization layer, a second source-drain metal layer and a second planarization layer sequentially stacked on a side of the base substrate; and
the multi-layer electrode plates of the storage capacitor are respectively located in multiple ones of the first gate layer, the second gate layer, the first source-drain metal layer and the second source-drain metal layer.

According to a third aspect of this disclosure, a display device is provided and includes the above-mentioned display panel.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a schematic structural diagram of a display panel according to some embodiments of this disclosure.

FIG. 2 is a schematic structural diagram of a display panel according to some embodiments of this disclosure.

FIG. 3 is a schematic partial cross-sectional structural diagram of a display panel according to some embodiments of this disclosure.

FIG. 4 is a schematic cross-sectional structure diagram of a display device according to some embodiments of this disclosure.

FIG. 5 is a schematic cross-sectional structure diagram of a storage capacitor according to some embodiments of this disclosure, in which only the electrical connections and overlapping positions of four-layer electrode plates are shown.

FIG. 6 is a schematic cross-sectional structure diagram of a storage capacitor according to some embodiments of this disclosure, in which only the electrical connections and overlapping positions of four-layer electrode plates are shown.

FIG. 7 is a schematic diagram of a partial structure of a transparent wiring layer in a second display region according to some embodiments of this disclosure.

FIG. 8 is a schematic diagram of a partial structure of a transparent wiring layer and a first gate layer in a second display region according to some embodiments of this disclosure.

FIG. 9 is a schematic diagram of a partial structure of a transparent wiring layer and a second gate layer in a second display region according to some embodiments of this disclosure.

FIG. 10 is a schematic diagram of a partial structure of a transparent wiring layer and a second source-drain metal layer in a second display region according to some embodiments of this disclosure.

FIG. 11 is a schematic structural diagram of a polysilicon semiconductor layer in a pixel driving region of a second display region according to some embodiments of this disclosure.

FIG. 12 is a schematic structural diagram of a first gate layer in a pixel driving region of a second display region according to some embodiments of this disclosure.

FIG. 13 is a schematic structural diagram of a second gate layer in a pixel driving region of a second display region according to some embodiments of this disclosure.

FIG. 14 is a schematic structural diagram of a first source-drain metal layer in a pixel driving region of a second display region according to some embodiments of this disclosure.

FIG. 15 is a schematic structural diagram of a transparent wiring layer in a pixel driving region of a second display region according to some embodiments of this disclosure.

FIG. 16 is a schematic structural diagram of a transparent wiring layer in a pixel driving region of a second display region according to some embodiments of this disclosure.

FIG. 17 is a schematic structural diagram of a second source-drain metal layer in a pixel driving region of a second display region according to some embodiments of this disclosure.

FIG. 18 is a schematic diagram of an equivalent circuit of a pixel driving circuit according to some embodiments of this disclosure.

FIG. 19 is a schematic diagram of electrical connection relationship of a pixel driving circuit in a second display region according to some embodiments of this disclosure, in which shaded rectangles indicated by Cst represent capacitance values of storage capacitors, and the larger the rectangle, the larger the capacitance value.

FIG. 20 is a schematic structural diagram of a pixel driving region according to some embodiments of this disclosure.

Explanation of reference signs are as follows.

| | | |
|---|---|---|
| PNL, display panel; | AA, display region; | BB, peripheral region; |
| B1, binding region; | A1, first display region; | A2, second display region; |

| | |
|---|---|
| C100, pixel driving circuit; | C200, light emitting element; |

C300, photosensitive component;

| F100, base substrate; | F200, driving circuit layer; | F300, pixel layer; |
|---|---|---|
| Cst, storage capacitor; | CP1, first electrode plate; | CP2, second electrode plate; |
| CP3, third electrode plate; | CP4, fourth electrode plate; | |
| Data, data voltage; | DataL, data lead; | |
| GL, scanning lead; | GL1, first scanning sub-lead; | GL2, second scanning sub-lead; |
| Gate, scanning signal; | EM, light control signal; | EML, light control lead; |

EML1, first light control sub-lead;
EML2, second light control sub-lead;

| | | |
|---|---|---|
| ReL, reset lead; | ReL1, first reset sub-lead; | ReL2, second reset sub-lead; |
| Reset, reset signal; | Vinit, initialization signal; | ViL, initialization lead; |

ViL1, first initialization sub-lead;
ViL2, second initialization sub-lead;

| | |
|---|---|
| VDD, first power voltage; | VDDL, first power voltage lead; |
| VDDL1, first power sub-lead; | VDDL2, second power sub-lead; |

VSS, second power voltage;

| | | |
|---|---|---|
| H1, row direction; | H11, first row direction; | H12, second row direction; |
| H2, column direction; | H21, first column direction; | H22, second column direction; |

SubA, pixel driving region;

| | |
|---|---|
| M1, driving transistor; | M1CNL, channel region of driving transistor; |
| M2, data writing transistor; | M2CNL, channel region of data writing transistor; |

M3, threshold compensation transistor;
M3CNL1, first channel region of threshold compensation transistor;
M3CNL2, second channel region of threshold compensation transistor;
M4, the first light control transistor;
M4CNL, channel region of first light control transistor;
M5, second light control transistor;
M5CNL, channel region of second light control transistor;

| | |
|---|---|
| M6, first reset transistor; | M6CNL1, first channel region of first reset transistor; |

M6CNL2, second channel region of first reset transistor;

| M7, second reset transistor; | M7CNL, channel region of second reset transistor; | |
|---|---|---|
| N1, first node; | N2, second node; | N3, third node; |
| N4, fourth node; | PL1, first conductive wiring; | PL2, second conductive wiring; |

| | |
|---|---|
| PL3, third conductive wiring; | PL4, fourth conductive wiring; |
| PL5, fifth conductive wiring; | PL6, sixth conductive wiring; |
| PL7, seventh conductive wiring; | PL8, eighth conductive wiring; |
| ML1, first conductive portion; | ML2, second conductive portion; |
| ML3, third conductive portion; | ML4, fourth conductive portion; |
| ML5, fifth conductive portion; | ML6, sixth conductive portion; |
| ML7, seventh conductive portion; | ML8, eighth conductive portion; |
| ML9, ninth conductive portion; | ML10, tenth conductive portion; |

ML11, eleventh conductive portion;

| | |
|---|---|
| HA1, first bottom via region; | HA2, second bottom via region; |
| HA3, third bottom via region; | HA4, fourth bottom via region; |
| HA5, fifth bottom via region; | HA6, sixth bottom via region; |
| HA7, seventh bottom via region; | HA8, eighth bottom via region; |
| HA9, ninth bottom via region; | HA10, tenth bottom via region; |
| HA11, eleventh bottom via region; | HA12, twelfth bottom via region; |
| HA13, thirteenth bottom via region; | HA14, fourteenth bottom via region; |
| HA15, fifteenth bottom via region; | HA16, sixteenth bottom via region; |
| HA17, seventeenth bottom via region; | HA18, eighteenth bottom via region; |
| HA19, nineteenth bottom via region; | HA20, twentieth bottom via region; |
| HA21, twenty-first bottom via region; | HA22, twenty-second bottom via region; |
| HA23, twenty-third bottom via region; | HA24, twenty-fourth bottom via region; |
| HA25, twenty-fifth bottom via region; | HA26, twenty-sixth bottom via region; |
| HA27, twenty-seventh bottom via region; | HA28, twenty-eighth bottom via region; |
| HA29, twenty-ninth bottom via region; | HA30, thirtieth bottom via region; |
| HB1, first top via region; | HB2, second top via region; |
| HB3, third top via region; | HB4, fourth top via region; |
| HB5, fifth top via region; | HB6, sixth top via region; |
| HB7, seventh top via region; | HB8, eighth top via region; |
| HB9, ninth top via region; | HB10, tenth top via region; |
| HB11, eleventh top via region; | HB12, twelfth top via region; |
| HB13, thirteenth top via region; | HB14, fourteenth top via region; |
| HB15, fifteenth top via region; | HB16, sixteenth top via region; |
| HB17, seventeenth top via region; | HB18, eighteenth top via region; |
| HB19, nineteenth top via region; | HB20, twentieth top via region; |
| HB21, twenty-first top via region; | HB22, twenty-second top via region; |
| HB23, twenty-third top via region; | HB24, twenty-fourth top via region; |
| HB25, twenty-fifth top via region; | HB26, twenty-sixth top via region; |
| HB27, twenty-seventh via region; | HB28, twenty-eighth via region; |
| HB29, the twenty-ninth via region; | HB30, thirtieth via region. |

### DETAILED DESCRIPTION

Exemplary embodiments will now be described more fully with reference to the accompanying drawings. Exemplary embodiments may, however, be embodied in many forms and should not be construed as limited to the embodiments set forth herein. Instead, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted. Furthermore, the drawings are merely schematic illustrations of this disclosure and are not necessarily drawn to scale.

The terms “a”, “an”, “the”, “said” and “at least one” are used to indicate the presence of one or more elements/components/etc.; the terms “comprise/include” and “have” are used to indicate an open and means that there may be additional elements/components/etc. in addition to the listed elements/components/etc.; the terms “first”, “second” and “third” etc. are only used as a marker, rather than a limit on the number of related objects.

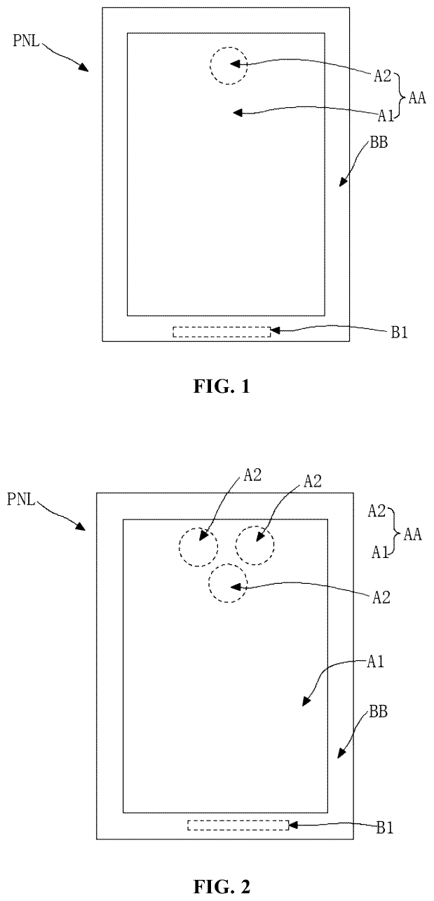

This disclosure provides a display panel and a display device including the display panel. FIG. 1 and FIG. 2 are top structural views of the display panel PNL provided by this disclosure. Referring to FIG. 1 and FIG. 2, the display panel PNL may include a display region AA and a peripheral region BB surrounding the display region AA; the display region AA may include a first display region A1 and a second display region A2 disposed adjacently. Herein, the light transmittance of the second display region A2 is greater than the light transmittance of the first display region A1.

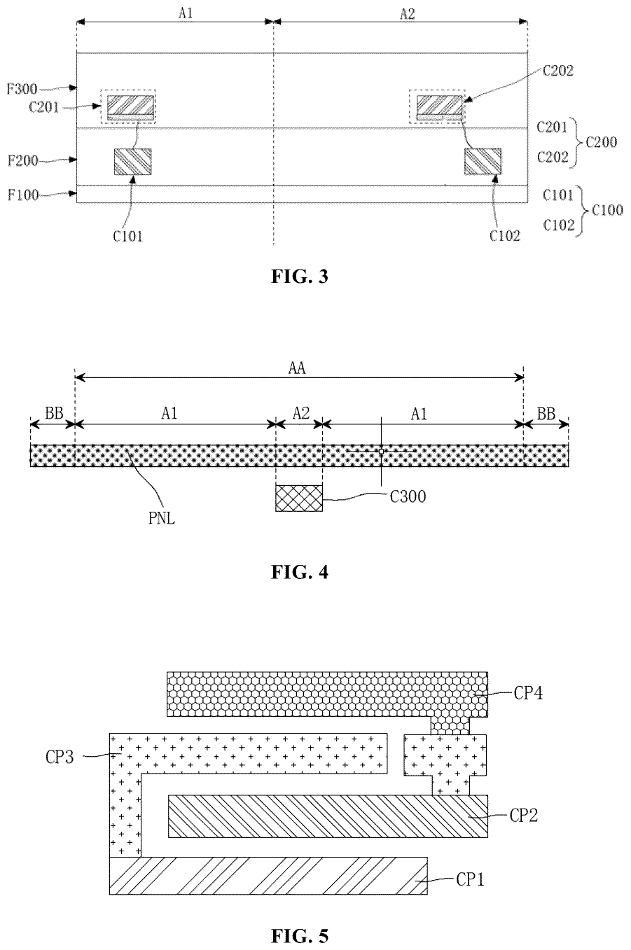

FIG. 3 is a schematic diagram of a partial structure of the display panel PNL provided by this disclosure. Referring to FIG. 3, the display panel may be provided with light emitting elements C200 in both the first display region A1 and the second display region A2, so that both the first display region A1 and the second display region A2 can realize screen display.

Referring to FIG. 4, a display device to which the display panel PNL is applied may include at least one photosensitive element C300. Herein, the photosensitive component C300 may be provided in one-to-one correspondence with the second display region A2, and the photosensitive component C300 can face the second display region A2 corresponding thereto, so as to receive light transmitted from the second display region A2. The photosensitive component C300 may have a photosensitive region for sensing light, and an orthographic projection of the photosensitive region on the base substrate F100 may be located in the second display region A2. The photosensitive component C300 may include one or more light sensors, such as a camera, an optical fingerprint recognition chip, a light intensity sensor, and the like. In some embodiments, the photosensitive component C300 may be a camera, for example, a CCD (Charge Coupled Device) camera; in this way, under-screen photography may be realized by the display device and the screen-to-body ratio of the display device may be increased.

Optionally, referring to FIG. 1 and FIG. 2, the second display region A2 may be embedded in the first display region A1, that is, the first display region A1 surrounds the second display region A2. When the number of the second display regions A2 is more than one, the second display regions A2 may be scattered or adjacent to each other. Also, in other embodiments of this disclosure, the second display region A2 may be located on one side of the first display region A1. For example, the edge of the second display region A2 may partially overlap with the inner edge of the peripheral region BB, so that the second display region A2 is arranged at the edge of the display region AA.

Optionally, the shape of any second display region A2 may be a circle, a square, a rhombus, a regular hexagon or other shapes. In some embodiments of this disclosure, the second display region A2 may be circular in shape.

The number of the second display region A2 may be one or more, whichever meets the configuration of the photosensitive component C300. In some embodiments of this disclosure, the number of the second display region A2 is one. In this way, the display device may be provided with an under-screen photosensitive component C300, for example, an under-screen camera or an under-screen optical fingerprint recognition chip may be provided. In some other embodiments of this disclosure, there are multiple second display regions A2. In this way, the display device may be provided with multiple photosensitive components C300, and any two photosensitive components C300 may be the same or different. For example, referring to FIG. 2, there are three second display regions A2 arranged adjacently. In this way, the display device may be provided with different photosensitive components C300 corresponding to the three second display regions A2 one-to-one, for example, three different photosensitive components C300 include an imaging camera, a depth-field camera, and an infrared camera.

Referring to FIG. 3, the display panel is provided with a pixel driving circuit C100 for driving light emitting elements, and an output terminal of the pixel driving circuit C100 is configured to electrically connect with pixel electrodes of corresponding light emitting elements.

Referring to FIG. 3, the pixel driving circuit C100 may be distributed in the first display region A1 and the second display region A2, where the pixel driving circuit C100 in the first display region may be configured to drive the light emitting element C200 in the first display region A1. The pixel driving circuit C100 located in the second display region A2 may be configured to drive the light emitting element C200 located in the second display region A2. In other words, the light emitting element C200 may include a first light emitting element C201 located in the first display region A1 and a second light emitting element C202 located in the second display region A2; the pixel driving circuit C100 may include a first pixel driving circuit C101 for driving the first light emitting element C201 and a second pixel driving circuit C102 for driving the second light emitting element C202. The first pixel driving circuit C101 may be provided in the first display region A1, and the second pixel driving circuit C102 may be provided in the second display region A2.

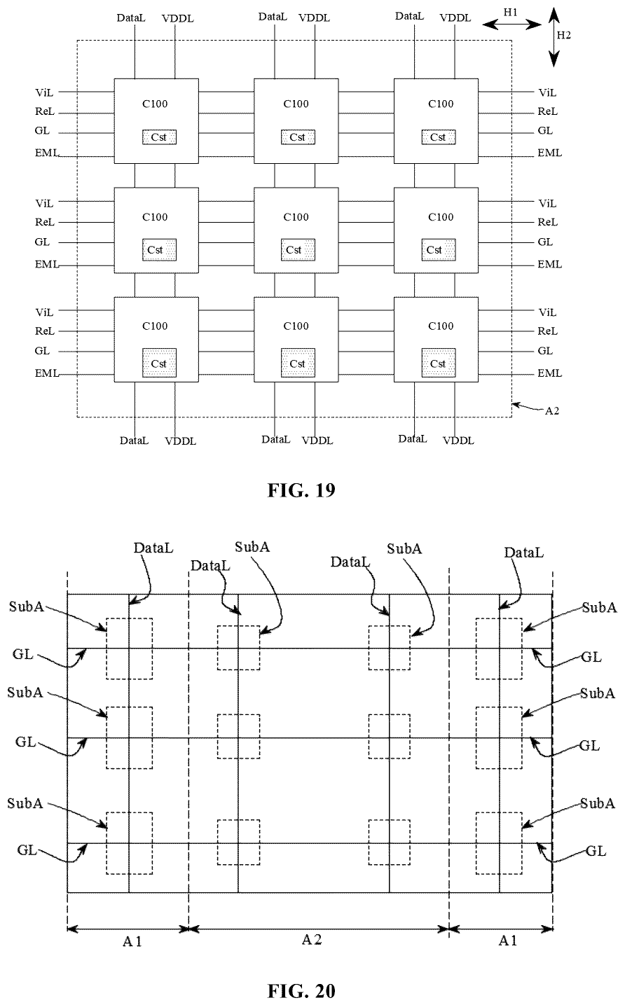

Referring to FIG. 19, the display panel includes signal lines connected to the pixel driving circuit, so as to load corresponding signals to the pixel driving circuit. Referring to FIG. 19, these signal lines may include a scanning lead GL for loading a scanning signal Gate, a data lead DataL for loading a data voltage Data, a first power lead VDDL for loading a first power voltage VDD, and the like. According to the difference of pixel driving circuits C100, the display panel may further include other signal lines. For example, when the pixel driving circuit C100 needs to load an initialization signal Vinit to certain nodes under the control of a reset signal Reset, the signal lines of the display panel may further include a reset lead ReL for loading the reset signal Reset and an initialization lead ViL for loading the initialization signal Vinit. For another example, when the pixel driving circuit C100 needs to output a driving current only under the control of a light emission control signal (or abbreviated as light control signal) EM, the signal lines of the display panel may further include a light emission control lead (or abbreviated as light control lead) EML for loading the light control signal EM.

Referring to FIG. 18, the pixel driving circuit C100 may include a storage capacitor Cst, a data writing transistor and a driving transistor. In some embodiments, the driving transistor M1 may be loaded with the first power voltage VDD and output the driving current under the control of the storage capacitor Cst. The data writing transistor M2 may be loaded with the data voltage Data and writing the data voltage Data into the storage capacitor Cst under the control of the scanning signal Gate. Therefore, the data writing transistor M2 is to be connected to the data voltage of the data lead DataL and the scanning lead GL, so as to receive the scanning signal Gate applied to the scanning lead GL and the data voltage Data applied to the data lead DataL. In this disclosure, the extending direction of the data lines DataL may be defined as the row direction of the display panel PNL, and the extending direction of the scanning leads GL may be defined as the column direction of the display panel PNL. In the display panel PNL provided in this disclosure, multiple pixel driving circuits C100 may be connected to one data lead DataL, and multiple pixel driving circuits C100 may be connected to one scanning lead GL. In this way, the display panel PNL can drive respective pixel driving circuits C100 in a progressive scanning (or referred to as line-by-line scanning) manner.

According to some embodiments of this disclosure, referring to FIG. 1, the peripheral region BB of the display panel PNL has a binding region B1 for electrically connecting with a driving chip or a circuit board to drive the display panel PNL. Further, the binding region is located at one end of the display panel PNL in the column direction. Furthermore, the second display region A2 is located at one end of the display region AA away from the binding region, and is provided close to the edge or corner of the display region AA.

In terms of film layer relationship, referring to FIG. 3, the display panel PNL may include a base substrate F100, a driving circuit layer F200, and a pixel layer F300 that are sequentially stacked. In some embodiments, the pixel driving circuit C100 may be disposed on the driving circuit layer F200, and the light emitting element C200 may be disposed on the pixel layer F300.

The base substrate F100 may be a base substrate F100 of inorganic material, or may be a base substrate F100 of organic material. For example, in some embodiments of this disclosure, the material of the base substrate F100 may be of glass material such as soda-lime glass, quartz glass, sapphire glass, or may be of metal material such as stainless steel, aluminum, nickel. In some other embodiments of this disclosure, the material of the base substrate F100 may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN) or a combination thereof. In some other embodiments of this disclosure, the base substrate F100 may also be a flexible base substrate F100. For example, the material of the base substrate F100 may be polyimide (PI). The base substrate F100 may also be a composite of multi-layer materials. For example, in some embodiments of this disclosure, the base substrate F100 may include a bottom film layer, a pressure-sensitive adhesive layer, a first polyimide layer and a second polyimide layer that are sequentially stacked.

In the driving circuit layer F200, any pixel driving circuit C100 may include a transistor and a storage capacitor. Further, the transistor may be a thin film transistor, and the thin film transistor may be a top gate thin film transistor, a bottom gate thin film transistor or a double gate thin film transistor; the material of the active layer of the thin film transistor may be amorphous silicon semiconductor, low temperature polysilicon semiconductor, metal oxide semiconductor, organic semiconductor or other types of semiconductor; and the thin film transistor may be an N-type thin film transistor or a P-type thin film transistor. In some embodiments of this disclosure, the thin film transistor is a low temperature polysilicon transistor.

It can be understood that, among the respective transistors in the pixel driving circuit C100, the types of any two transistors may be the same or different. Exemplarily, in some embodiments of a pixel driving circuit C100, some transistors may be N-type transistors and some transistors may be P-type transistors. As another example, in some other embodiments of a pixel driving circuit C100, the material of the active layer of some transistors may be low-temperature polysilicon semiconductor, and the material of the active layer of some transistors may be metal oxide semiconductor.

The transistor may have a first electrode, a second electrode, and a gate, and one of the first electrode and the second electrode may be a source of the transistor and the other may be a drain of the transistor. It can be understood that the source and the drain of the transistor are two opposite concepts that may be interchanged; when the working state of the transistor changes, for example, the direction of the current changes, the source and the drain of the transistor may be interchanged.

Optionally, the driving circuit layer F200 may include a semiconductor layer, a gate insulating layer, a gate layer, an interlayer dielectric layer, a source-drain metal layer, a planarization layer and the like stacked between the base substrate F100 and the pixel layer F300. Each thin film transistor and storage capacitor may be formed of film layers such as a semiconductor layer, a gate insulating layer, a gate layer, an interlayer dielectric layer, and a source-drain metal layer. Herein, the positional relationship of respective film layers may be determined according to the film layer structure of the thin film transistor. For example, in some embodiments of this disclosure, the driving circuit layer F200 may include a semiconductor layer, a gate insulating layer, a gate layer, an interlayer dielectric layer, and a source-drain metal layer that are sequentially stacked, and the thin film transistor formed in such manner is a top-gate thin film transistor. For another example, in some other embodiments of this disclosure, the driving circuit layer F200 may include a gate layer, a gate insulating layer, a semiconductor layer, an interlayer dielectric layer, and a source-drain metal layer that are sequentially stacked, so that the formed thin film transistor is a bottom gate thin film transistor.

Optionally, the driving circuit layer F200 may also adopt a double gate layer structure, that is, the gate layer may include a first gate layer and a second gate layer, and the gate insulating layer may include a first gate insulating layer for isolating the semiconductor layer and the first gate layer, and a second gate insulating layer for isolating the first gate layer and the second gate layer. For example, in some embodiments of this disclosure, the driving circuit layer F200 may include a semiconductor layer, a first gate insulating layer, a first gate layer, a second gate electrode insulating layer, a second gate layer, an interlayer dielectric layer and a source-drain metal layer that are sequentially stacked on one side of the base substrate F100.

Optionally, the driving circuit layer F200 may also adopt a dual source-drain metal layer structure, that is, the source-drain metal layer may include a first source-drain metal layer and a second source-drain metal layer, and the planarization layer may include a first planarization layer and a second planarization layer. The first source-drain metal layer, the first planarization layer, the second source-drain metal layer, and the second planarization layer are sequentially stacked on one side of the base substrate. For example, in some embodiments of this disclosure, the driving circuit layer F200 may include a semiconductor layer, a gate insulating layer, a gate layer, an interlayer dielectric layer, a first source-drain metal layer, a first planarization layer, a second source-drain metal layer and a second planarization layer that are sequentially stacked on one side of the base substrate F100.

Optionally, the driving circuit layer F200 may further include a passivation layer, and the passivation layer may be disposed on the surface of the source-drain metal layer away from the base substrate F100, so as to protect the source-drain metal layer.

Optionally, the driving circuit layer F200 may further include a buffer material layer disposed between the base substrate F100 and the semiconductor layer, and the semiconductor layer, the gate layer and the like are located on a side of the buffer material layer away from the base substrate F100. The material of the buffer material layer may be inorganic insulating material such as silicon oxide and silicon nitride. The buffer material layer may include one layer of inorganic material, or may include inorganic materials stacked in multiple layers.

Optionally, the driving circuit layer F200 may further include a transparent wiring layer. In the second display region A2, part of signal leads or part of lead segments of the signal leads may be disposed on the transparent wiring layer, so as to increase the light transmittance of the second display region A2.

Optionally, the pixel layer F300 may be disposed on a side of the driving circuit layer F200 away from the base substrate F100, and it may be provided with a light emitting element C200 as a sub-pixel of the display panel PNL. In some embodiments, the light emitting element C200 may be OLED (organic electroluminescent diode), Micro LED (micro light emitting diode), Mini LED (miniature light emitting diode), QD-OLED (quantum dot-organic electroluminescent diode) or other light emitting element. As follows, taking the light emitting element C200 as an organic electroluminescent diode as an example, the structure of the pixel layer will be briefly introduced. It can be understood that the structure of the pixel layer may also be formed in other structures, as long as being able to provide a current-driven light emitting element C200.

In this example, the pixel layer may include a pixel electrode layer, a pixel definition layer, a support pillar layer, an organic light emitting functional layer and a common electrode layer that are stacked in sequence. In some embodiments, the pixel electrode layer has a plurality of pixel electrodes in the display region of the display panel; the pixel definition layer has a plurality of penetrating pixel openings corresponding to the plurality of pixel electrodes one-to-one in the display region, and any one of the pixel openings exposes at least a partial region of a corresponding pixel electrode. The support pillar layer includes a plurality of support pillars in the display region, and the support pillars are located on the surface of the pixel definition layer away from the base substrate F100, so as to support a fine metal mask (FMM) during the evaporation process. The organic light emitting functional layer at least covers the pixel electrodes exposed by the pixel definition layer. In some embodiments, the organic light emitting functional layer may include an organic electroluminescent material layer, and may include one or more of a hole injection layer, a hole transport layer, an electron blocking layer, a hole blocking layer, an electron transport layer, and an electron injection layer. Each film layer of the organic light emitting functional layer may be prepared by the evaporation process, and an FMM or an open mask may be used to define the pattern of each film layer during evaporation. The common electrode layer may cover the organic light emitting functional layer in the display region. In this way, the pixel electrode, the common electrode layer and the organic light emitting functional layer located between the pixel electrode and the common electrode layer form an organic light emitting diode, and any organic light emitting diode may be used as a sub-pixel of the display panel.

In some embodiments, the pixel layer F300 may further include a light extraction layer located on a side of the common electrode layer away from the base substrate F100, so as to enhance the light extraction efficiency of the organic light emitting diode.

Optionally, the display panel may further include a thin film encapsulation layer. The thin film encapsulation layer is provided on the surface of the pixel layer F300 away from the base substrate F100, and may include inorganic encapsulation layers and organic encapsulation layers that are alternately stacked. In some embodiments, the inorganic encapsulation layer can effectively block moisture and oxygen from the outside, and prevent material degradation caused by water and oxygen intrusion into the organic light emitting functional layer. Alternatively, an edge of the inorganic encapsulation layer may be located in the peripheral region. The organic encapsulation layer is located between two adjacent inorganic encapsulation layers, so as to realize planarization and weaken the stress between the inorganic encapsulation layers. In some embodiments, the edge of the organic encapsulation layer may be located between the edge of the display region and the edge of the inorganic encapsulation layer. Exemplarily, the thin film encapsulation layer includes a first inorganic encapsulation layer, an organic encapsulation layer and a second inorganic encapsulation layer stacked in sequence on a side of the pixel layer away from the base substrate.

Optionally, the display panel may further include a touch function layer, and the touch function layer is provided on a side of the thin film encapsulation layer away from the base substrate for realizing touch operation of the display panel.

Optionally, the display panel may further include an anti-reflection layer, which may be provided on a side of the thin film encapsulation layer away from the pixel layer, so as to reduce reflection of ambient light on the display panel, thereby reducing the impact of ambient light on the display effect. In some embodiments of this disclosure, the anti-reflection layer may include a color filter layer and a black matrix layer that are stacked, so as to reduce the interference of ambient light while avoiding reducing the light transmittance of the display panel. In some other embodiments of this disclosure, the anti-reflection layer may be a polarizer, such as a patterned coated-type circular polarizer. Further, the anti-reflection layer may be provided on a side of the touch function layer away from the base substrate.

In the display panel PNL provided in this disclosure, in order to make the second display region A2 have greater light transmittance, the structure of the display panel PNL may lead to a difference, in settings or signal lines, between the pixel driving circuit C100 in the second display region A2 and that in the first display region A1. On the one hand, this difference may cause a difference in the brightness of the light emitting element C200 in the second display region A2 and the brightness of the light emitting element C200 in the first display region A1. On the other hand, it may also cause a relatively great difference in the brightness of the light emitting elements C200 at different positions in the second display region A2. The existence of such kinds of differences (non-uniformity) makes it difficult to realize the brightness uniformity of the display panel PNL through compensation, and the compensation effect is not good. In order to solve this problem, the inventor(s) has carried out a large number of tests, and in the tests, it was unexpectedly found that, by adjusting the capacitance value of the storage capacitor Cst in the pixel driving circuit C100 (second pixel driving circuit C102) in the second display region A2, the brightness of the light emitting element C200 (second light emitting element C202) in the second display region A2 can be adjusted, thereby achieving the brightness uniformity of the light emitting elements C200 in the second display region A2 by adjusting the capacitance value of the storage capacitor Cst of the pixel driving circuit C100 in the second display region A2. Specifically, the inventor(s) found that when the capacitance value of the storage capacitor Cst of the pixel driving circuit C100 in the second display region A2 is increased, the brightness value of the light emitting element C200 driven by the pixel driving circuit C100 can be increased. Accordingly, when the capacitance value of the storage capacitor Cst of the pixel driving circuit C100 in the second display region A2 is reduced, the brightness value of the light emitting element C200 driven by the pixel driving circuit C100 can be reduced. Based on this finding, referring to FIG. 19, in the display panel PNL provided by this disclosure, in the second display region A2 of the display panel PNL, the capacitance values of the storage capacitors of the pixel driving circuits C100 sequentially connected to the same data lead DataL change gradually. In this way, the gradual change of the capacitance values of the storage capacitors Cst of the pixel driving circuits C100 in the second display region A2 can generate a gradual change trend for the luminance of the light emitting elements C200 in the second display region A2. Such gradual change trend may counterbalance the gradual change trend of the brightness originally occurred in the light emitting elements C200 in the display region A2, thereby achieving the brightness uniformity of the light emitting elements C200 in the second display region A2. Further, when the brightness uniformity is achieved in the second display region A2, the brightness uniformity of the light emitting elements C200 in the first display region A1 and the second display region A2 can be achieved in the display panel PNL through a compensation method more conveniently and better, thereby improving the display effect of the display panel PNL.

Exemplarily, in some related technologies, the capacitance values of the storage capacitors Cst in the second display region A2 are the same. Along a column direction away from the binding region, the brightness of light emitting elements C200 driven by respective pixel driving circuits C100 sequentially connected to the same data lead DataL increases in sequence. This results in non-uniform brightness of the light emitting elements C200 in the second display region A2. However, in a technical solution of this disclosure, along a direction away from the binding region, the capacitance values of the storage capacitors of the pixel driving circuits C100 connected to the same data lead DataL in the second display region gradually decrease. In this way, the settings of the storage capacitors Cst according to the technical solution of this disclosure can provide a reverse gradual trend for the light emitting brightness of the light emitting elements C200 in the second display region A2, thereby achieving the brightness uniformity of respective light emitting elements C200 in the second display region A2.

It can be understood that if, in the technical solution adopted in the related art, the capacitance values of the storage capacitors Cst in the second display region A2 are the same, then, along the column direction away from the binding region, the light emitting elements C200 driven by the respective pixel driving circuits C100, that are sequentially connected to the same data lead DataL, have their light emitting brightness decrease sequentially. Then this related technical solution may be improved according to the technical solution of the display panel provided in this disclosure, and then form another technical solution of this disclosure. In such new technical solution, along the direction away from the binding region, the capacitance values of the storage capacitors of the respective pixel driving circuits C100, in the second display region and connected to the same data lead DataL, gradually increase.

In this disclosure, referring to FIG. 20, the display panel PNL includes a pixel driving region SubA for providing pixel driving circuits C100, and each pixel driving circuit C100 is provided in a one-to-one correspondence with each pixel driving region SubA. The first electrode, the second electrode and the gate of each transistor of any one pixel driving circuit C100 are provided in the pixel driving region SubA corresponding to the pixel driving circuit C100. In some embodiments of this disclosure, the area of the pixel driving region SubA in the second display region is smaller than the area of the pixel driving region SubA in the first display region. In other words, the pixel driving circuit C100 in the second display region A2 may be compressed, so as to reduce the area of its corresponding pixel driving region SubA, thereby preventing the pixel driving circuit C100 from blocking light and reducing the light transmittance of the second display region A2. This setting may cause the capacitance value of the storage capacitor Cst of the pixel driving circuit C100 in the second display region A2 to decrease, and then the voltage on the storage capacitor Cst may be susceptible to the scanning signal Gate that transitions on the scanning lead GL, thereby further causing the following trend. The brightness of the light emitting elements C200 in the second display region A2 is likely to be uneven, and the brightness of the light emitting elements C200 in the second display region A2 and the first display region A1 is different. Exemplarily, such embodiments tend to produce the following trend: the voltage (the gate voltage of the driving transistor M1) on the storage capacitor Cst in the second display region A2 is affected by the scanning signal Gate that transitions on the scanning lead GL and increases, so that the brightness of the light emitting elements C200 in the second display region A2 is lower than the brightness of the light emitting elements C200 in the first display region A1. However, in this disclosure, one or more of these tendencies may be weakened or eliminated by adjusting the capacitance values of the storage capacitors Cst in the second display region A2. For example, the trend of non-uniform brightness of the light emitting elements C200 in the second display region A2 can be weakened by making (capacitance values of) the storage capacitors Cst gradually decrease along the direction away from the binding region. In this way, although the technical solution of compressing the pixel driving circuit C100 in the second display region A2 is adopted in some embodiments of this disclosure, some or all of the negative effects caused by compressing the pixel driving circuit C100 may be overcome by adjusting the capacitance values of the storage capacitors Cst in the second display region A2.

According to some embodiments of this disclosure, in the second display region A2, the material of the part of the signal line outside the pixel driving region SubA is a transparent conductive material. In this way, conduction of the signal lines can be ensured, and the light transmittance of the second display region A2 can be prevented from decreasing due to being blocked by the signal lines. Further, the transparent conductive material may be a transparent conductive metal oxide material, such as IGZO (Indium Gallium Zinc Oxide), ITO (Indium Tin Oxide), and the like. In related art, transparent conductive materials have a large square resistance. If the signal lines are partially made of the transparent conductive material, it may cause a large voltage drop during the transmission of signal, which will intensify the brightness non-uniformity of the light emitting elements C200 in the second display region A2. For example, the data lead DataL is at least partially made of transparent conductive material in the second display region A2, which makes the data voltage Data have a relatively large voltage drop in the column direction. Compared to the pixel driving circuit C100 close to the binding region, the actual data voltage Data received by the pixel driving circuit C100 away from the binding region is smaller and the brightness of the light emitting element is greater. However, in some embodiments of this disclosure, based on the implementation manner in which the storage capacitances Cst are sequentially decreased in the second display region A2 along the direction away from the binding region, the brightness of the light emitting elements C200 in the second display region A2 may be made to have a decreasing trend, which is opposite to the trend of the brightness of the light emitting elements C200 caused by the square resistance of the data lead DataL, along the direction away from the binding region, thereby producing a counteracting effect. In this way, the technical solution of this disclosure can not only realize the uniform brightness of the light emitting elements C200 in the second display region A2, but also improve the light transmittance of the second display region A2 by using the transparent conductive material to prepare part of the lead segments of the signal leads in the second display region A2.

Optionally, in the display panel PNL of this disclosure, the driving circuit layer may have a transparent wiring layer; in the second display region, the part of the signal line outside the pixel driving region SubA may be provided on the transparent wiring layer.

Exemplarily, in some embodiments of this disclosure, the driving circuit layer includes a semiconductor layer, a first gate layer, a second gate layer, a first source-drain metal layer, a second source-drain metal layer that are stacked in sequence; and the pixel layer is provided with a pixel electrode layer. The display panel further includes a transparent wiring layer, and the transparent wiring layer is located between any adjacent two of the semiconductor layer, the first gate layer, the second gate layer, the first source-drain metal layer, the second source-drain metal layer, and the pixel electrode layer. In the second display region, the part of the signal line outside the pixel driving region SubA is located in the transparent wiring layer.

In some embodiments of this disclosure, in the second display region A2, the capacitance values of the storage capacitors of respective pixel driving circuits C100 sequentially connected to the same scanning lead GL are the same. In this way, the design and manufacture of the pixel driving circuits C100 in the second display region A2 can be simplified, thereby reducing the cost of the display panel PNL. In addition, it was found in the test that the difference in brightness of the light emitting elements C200 in the second display region A2 is small or basically zero along the row direction, so that the same storage capacitors Cst of the pixel driving circuits C100 connected to the same scanning lead GL in the second display region A2 will not increase the brightness difference of the light emitting elements C200 in the second display region A2.

Optionally, the capacitance value of the storage capacitor Cst may be adjusted by adjusting the total overlapping area of plates of the storage capacitor Cst. When the total overlapping area of the plates of the storage capacitor Cst is increased, the capacitance value of the storage capacitor Cst can be increased; conversely, when the total overlapping area of the plates of the storage capacitor Cst is reduced, the capacitance value of the storage capacitor Cst can be reduced.

Exemplarily, the storage capacitor of the pixel driving circuit C100 includes multi-layer electrode plates sequentially stacked on one side of the base substrate of the display panel. In some embodiments, odd-numbered layers of the electrode plates are electrically connected to each other, and even-numbered layers of the electrode plates are electrically connected to each other; two adjacent layers of the electrode plates overlap and are electrically insulated with each other; and a total overlapping area of the electrode plates of the storage capacitor is equal to a sum of overlapping areas between any two adjacent layers of the electrode plates.

Optionally, along the direction away from the binding region, the total overlapping areas of the plates of the storage capacitors of respective pixel driving circuits C100 located in the second display region and connected to the same data lead DataL gradually decrease. Thus, along the direction away from the binding region, the capacitance values of the storage capacitors of the respective pixel driving circuits C100 located in the second display region and connected to the same data lead DataL gradually decrease.

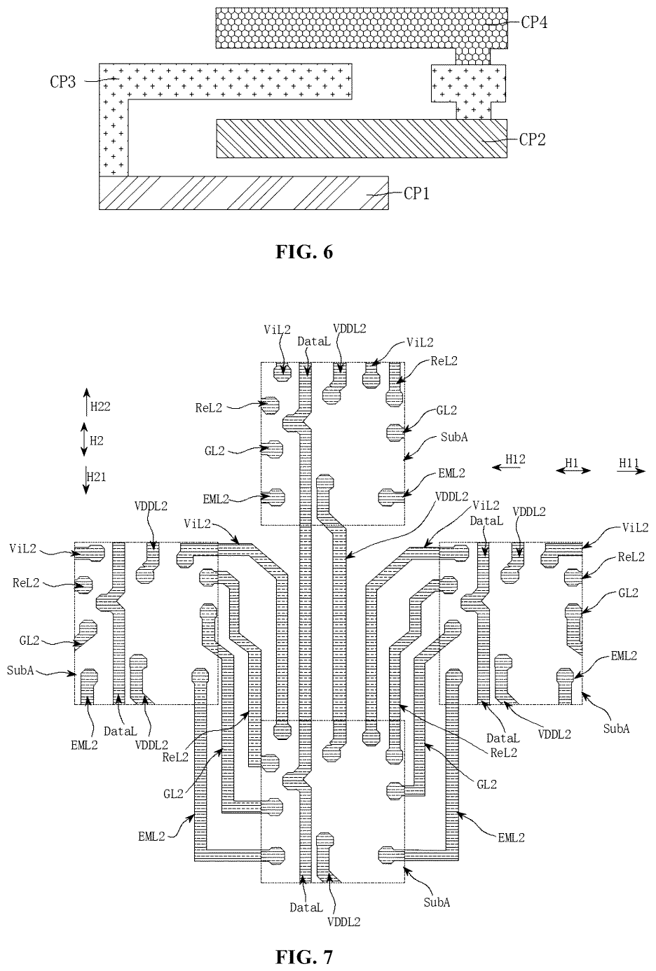

According to some embodiments of this disclosure, referring to FIG. 5 and FIG. 6, in the second display region A2, the storage capacitor Cst may include four layers of electrode plates (CP1-CP4), so that the capacitance value of the storage capacitor Cst in the second display region A2 can be enlarged as much as possible, thereby preventing the storage capacitor Cst from being easily interfered by other signals when the capacitance value thereof is small. Further, referring to FIG. 20, the area of the pixel driving region SubA in the second display region A2 is smaller than the area of the pixel driving region SubA in the first display region A1. In this case, the storage capacitor Cst in the second display region A2 provided with four layers of electrode plates can have its capacitance value with decreased difference from the capacitance value of the storage capacitor Cst in the first display region A1, which in turn facilitates reducing the brightness difference between the light emitting elements C200 in the first display region A1 and that in the second display region A2. Exemplarily, the storage capacitor Cst in the first display region A1 may include two layers of electrode plates, for example, a first electrode plate CP1 located at the first gate layer and a second electrode plate CP2 located at the second gate layer, where the first electrode plate CP1 and the second electrode plate CP2 overlap each other and are electrically insulated. The storage capacitor Cst in the second display region A2 may include four layers of electrode plates, for example, a first electrode plate CP1 located at the first gate layer, a second electrode plate CP2 located at the second gate layer, a third electrode plate CP3 located at the first source-drain metal layer and a fourth electrode plate CP4 located at the second source-drain metal layer, where any two adjacent layers of electrode plates overlap each other and are electrically insulated. In some embodiments, the first electrode plate CP1 and the third electrode plate CP3 are directly or indirectly electrically connected through via holes; and the second electrode plate CP2 and the fourth electrode plate CP4 are directly or indirectly electrically connected through via holes.

In this disclosure, the overlapping area between the first electrode plate CP1 and the second electrode plate CP2 is defined as a first overlapping area; the overlapping area between the second electrode plate CP2 and the third electrode plate CP3 is defined as a second overlapping area; and the overlapping area between the third electrode plate CP3 and the fourth electrode plate CP4 is defined as a third overlapping area.

In some embodiments of this disclosure, along the direction away from the binding region B1, at least one of the first overlapping areas, the second overlapping areas and the third overlapping areas of the storage capacitors of respective pixel driving circuits C100 located in the second display region A2 and connected to the same data lead DataL decrease gradually. For example, along the direction away from the binding region, the storage capacitors Cst may only have their first overlapping areas, or their second overlapping areas, or their third overlapping areas decreased; or may have two of the three overlapping areas or all three overlapping areas decreased.

In this disclosure, when reducing the overlapping area between two adjacent layers of electrode plates, the size of one or two layers of electrode plates may be reduced, or the position of one or two layers of electrode plates may be adjusted (as shown in FIG. 5 and FIG. 6, there are differences in the positions of the electrode plates between FIG. 5 and FIG. 6), or the above two strategies may be adopted at the same time, as long as the overlapping area between two adjacent layers of electrode plates can be reduced.

It can be understood that, in this disclosure, the capacitance values of the storage capacitors of different pixel driving circuits C100 may also be adjusted in other manners. For example, the thickness of the insulating layer between the electrode plates of the storage capacitor, the dielectric constant of the insulating material may be adjusted, as long as the capacitance value of the storage capacitor can be changed.

In some embodiments of this disclosure, the pixel driving circuit C100 includes a driving transistor M1 for generating driving current; the first electrode plate CP1 of the storage capacitor is also used as the gate of the driving transistor M1; along the direction away from the binding region, areas of the first electrode plates CP1 of the storage capacitors of respective pixel driving circuits C100 connected to the same data lead DataL in the second display region remain unchanged. In this way, the performance of the driving transistors M1 of the respective pixel driving circuits C100 in the second display region A2 can be guaranteed to be unchanged, thereby avoiding increasing the brightness difference of the light emitting elements C200 in the second display region A2 due to the change of current characteristic of the driving transistors M1.

An exemplary display panel PNL is provided as follows, in order to further explain and describe the specific structure, principle and effect of the display panel PNL of this disclosure. It can be understood that the exemplary display panel PNL is only one of specific implementation manners of the display panel PNL provided by this disclosure, rather than a specific limitation on the display panel PNL of this disclosure. The display panel PNL of this disclosure can also be implemented in other ways than the exemplary display panel PNL.

In this exemplary display panel PNL, referring to FIG. 18, the pixel driving circuit C100 may be a 7T1C-structured pixel driving circuit C100, which may include a driving transistor M1, a data writing transistor M2, a threshold compensation transistor M3, a first light control transistor (or abbreviated as light control transistor) M4, a second light control transistor M5, a first reset transistor M6, a second reset transistor M7 and a storage capacitor Cst.

The driving transistor M1 has a first electrode, a second electrode and a gate, where the first electrode of the driving transistor M1 is connected to a first node N1, the second electrode of the driving transistor M1 is connected to a third node N3, and the gate of the driving transistor M1 is connected to a second node N2.

The data writing transistor M2 has a first electrode, a second electrode and a gate, where the first electrode of the data writing transistor M2 is configured to load the data voltage Data, the second electrode of the data writing transistor M2 is connected to the first node N1, and the gate of the data writing transistor M2 is configured to load the scanning signal Gate.

The threshold compensation transistor M3 has a first electrode, a second electrode and a gate, where the first electrode of the threshold compensation transistor M3 is connected to the second node N2, the second electrode of the threshold compensation transistor M3 is connected to the third node N3, and the gate of the threshold compensation transistor M3 is configured to load the scanning signal Gate.

The first light control transistor M4 has a first electrode, a second electrode and a gate, where the first electrode of the first light control transistor M4 is configured to load the first power voltage VDD, the second electrode of the first light control transistor M4 is connected to the first node N1, and the gate of the first light control transistor M4 is configured to load the light control signal EM.

The second light control transistor M5 has a first electrode, a second electrode and a gate, where the first electrode of the second light control transistor M5 is connected to the third node N3, the second electrode of the second light control transistor M5 is connected to a fourth node N4, and the gate of the second light control transistor M5 is configured to load the light control signal EM.

The first reset transistor M6 has a first electrode, a second electrode and a gate, where the first electrode of the first reset transistor M6 is configured to load the initialization signal Vinit, the second electrode of the first reset transistor M6 is connected to the second node N2, and the gate of the first reset transistor M6 is configured to load the reset signal Reset.

The second reset transistor M7 has a first electrode, a second electrode and a gate, where the first electrode of the second reset transistor M7 is configured to load the initialization signal Vinit, the second electrode of the second reset transistor M7 is connected to the fourth node N4, and the gate of the second reset transistor M7 is configured to load the scanning signal Gate.

One end of the storage capacitor Cst is connected to the second node N2, and the other end thereof is configured to load the first power voltage VDD.

In the exemplary display panel PNL, the pixel electrode of the light emitting element C200 may be connected to the fourth node N4, and the common electrode of the light emitting element C200 may be configured to load the second power voltage VSS. In this way, the pixel driving circuit C100 can drive the light emitting element C200 connected to the pixel driving circuit C100 to emit light.

In some exemplary embodiments, along the direction away from the binding region, the capacitance values of the storage capacitors of respective pixel driving circuits C100 connected to the same data lead DataL in the second display region gradually decrease. In the second display region, the capacitance values of the storage capacitors of respective pixel driving circuits C100 sequentially connected to the same scanning lead GL are the same.

In terms of film layer structure, the exemplary display panel PNL includes a base substrate, a driving circuit layer and a pixel layer that are stacked in sequence. In some embodiments, the driving circuit layer includes a buffer material layer, a polysilicon semiconductor layer, a first gate insulating layer, a first gate layer, a second gate insulating layer, a second gate layer, an inter-dielectric layer, a first source-drain metal layer, a first planarization layer, a transparent wiring layer, a third planarization layer, a second source-drain metal layer, and a second planarization layer that are stacked sequentially on one side of the base substrate. The pixel layer is provided with an organic electroluminescent diode as a light emitting element, and the pixel electrode of the organic electroluminescent diode is electrically connected to the pixel driving circuit C100 located in the driving circuit layer.

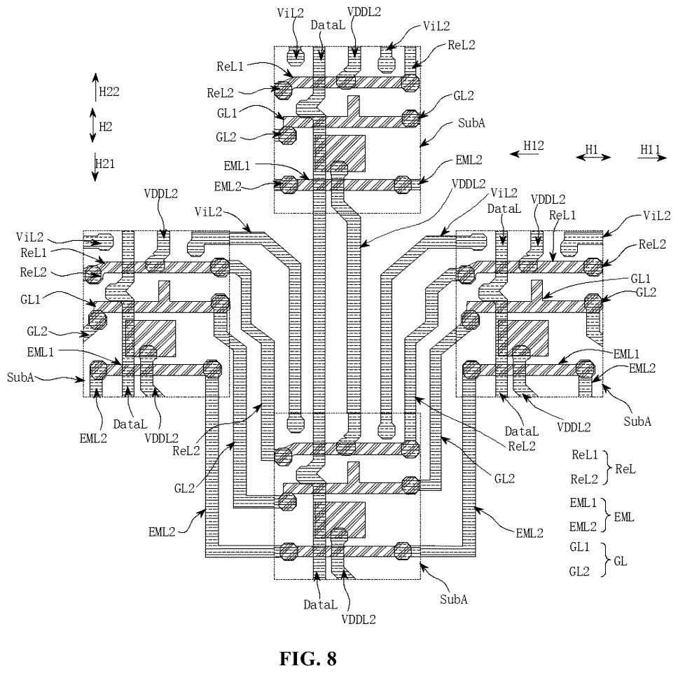

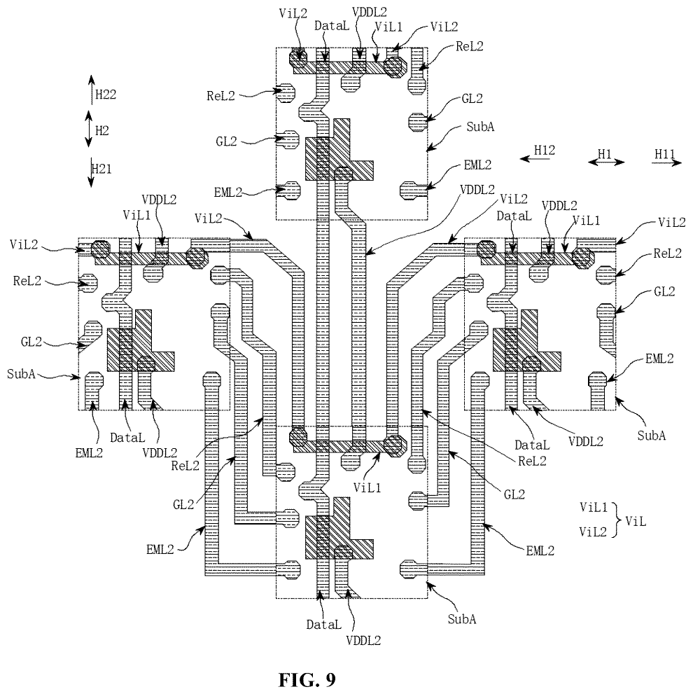

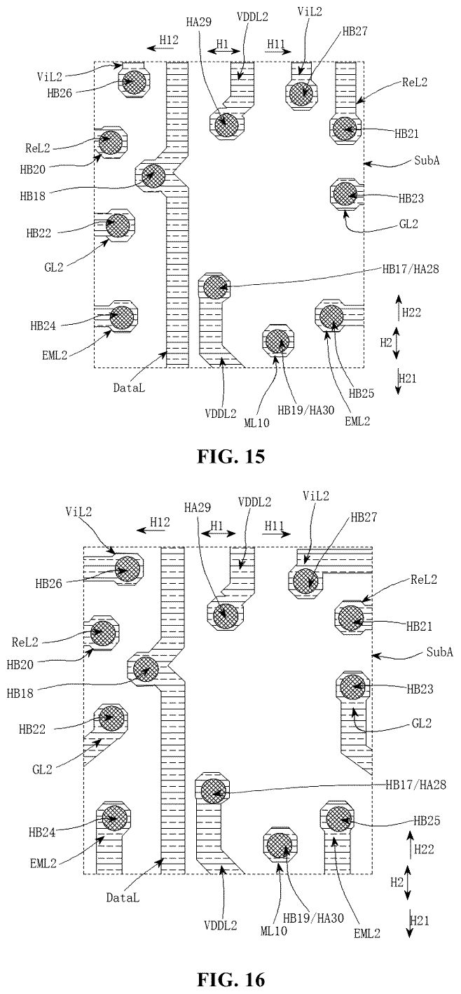

Referring to FIG. 8, in the second display region A2, the scanning leads GL include first scanning sub-leads GL1 and second scanning sub-leads GL2 that are alternately arranged and electrically connected in sequence. In some embodiments, referring to FIG. 8 and FIG. 12, the first scanning sub-lead GL1 is located in the pixel driving region SubA and is located in the first gate layer; referring to FIG. 7, FIG. 8 and FIG. 15, the second scanning sub-lead GL2 is located in the transparent wiring layer, and is electrically connected to the first scanning sub-lead GL1 through a via hole.

Referring to FIG. 8, in the second display region A2, the light emission control leads (or abbreviated as light control leads) EML include first light control sub-leads (or abbreviated as light control sub-leads) EML1 and second light control sub-leads EML2 that are alternately arranged and electrically connected in sequence. In some embodiments, referring to FIG. 8 and FIG. 12, the first light control sub-lead EML1 is located in the pixel driving region SubA and is located in the first gate layer; referring to FIG. 7, FIG. 8 and FIG. 15, the second light control sub-lead EML2 is located in the transparent wiring layer, and is electrically connected to the first light control sub-lead EML1 through a via hole.

Referring to FIG. 8, in the second display region A2, the reset leads ReL include first reset sub-leads ReL1 and second reset sub-leads ReL2 that are alternately arranged and electrically connected in sequence. In some embodiments, referring to FIG. 8 and FIG. 12, the first reset sub-lead ReL1 is located in the pixel driving region SubA and is located in the first gate layer; referring to FIG. 7, FIG. 8 and FIG. 15, the second reset sub-lead ReL2 is located in the transparent wiring layer, and is electrically connected to the first reset sub-lead ReL1 through a via hole.

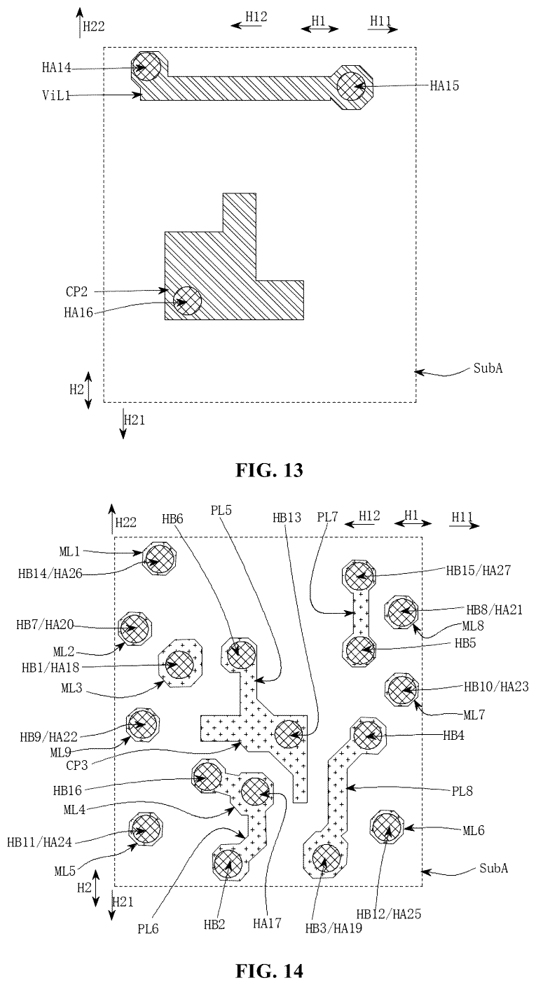

Referring to FIG. 9, in the second display region A2, the initialization leads ViL include first initialization sub-leads ViL1 and second initialization sub-leads ViL2 that are alternately arranged and electrically connected in sequence. In some embodiments, referring to FIG. 9 and FIG. 13, the first initialization sub-lead ViL1 is located in the pixel driving region SubA and is located in the second gate layer; referring to FIG. 7, FIG. 9 and FIG. 15, the second initialization sub-lead ViL2 is located in the transparent wiring layer, and is electrically connected to the first initialization sub-lead ViL1 through a via hole.

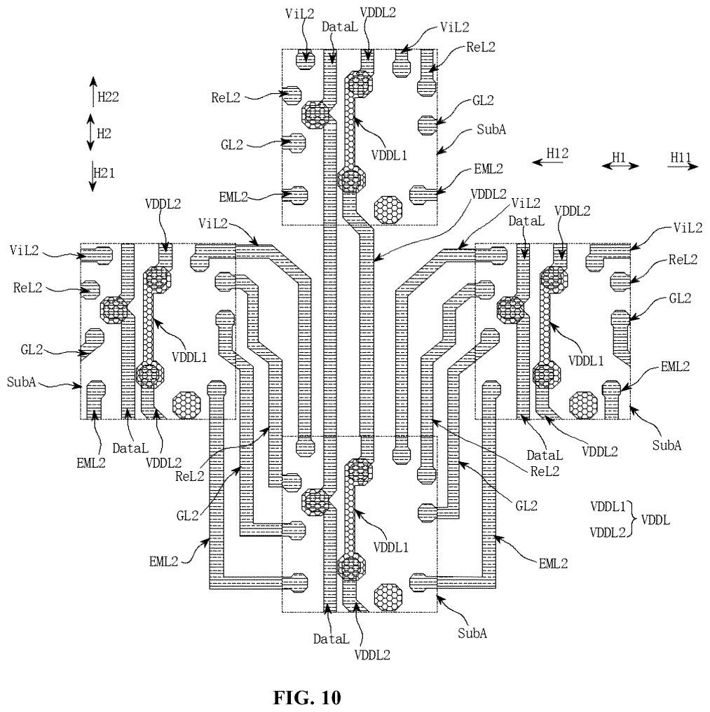

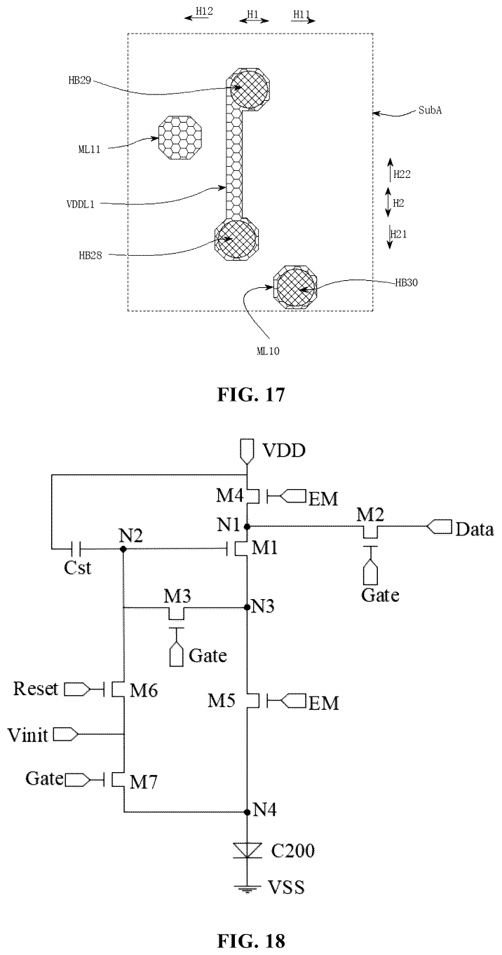

Referring to FIG. 10, in the second display region A2, the first power voltage lead VDDL includes first power sub-leads VDDL1 and second power sub-leads VDDL2 that are arranged alternately and electrically connected in sequence. In some embodiments, referring to FIG. 10 and FIG. 17, the first power sub-lead VDDL1 is located in the pixel driving region SubA and is located in the second source-drain metal layer; referring to FIG. 7, FIG. 10 and FIG. 15, the second power sub-lead VDDL2 is located in the transparent wiring layer, and is electrically connected to the first power sub-lead VDDL1 through a via hole.

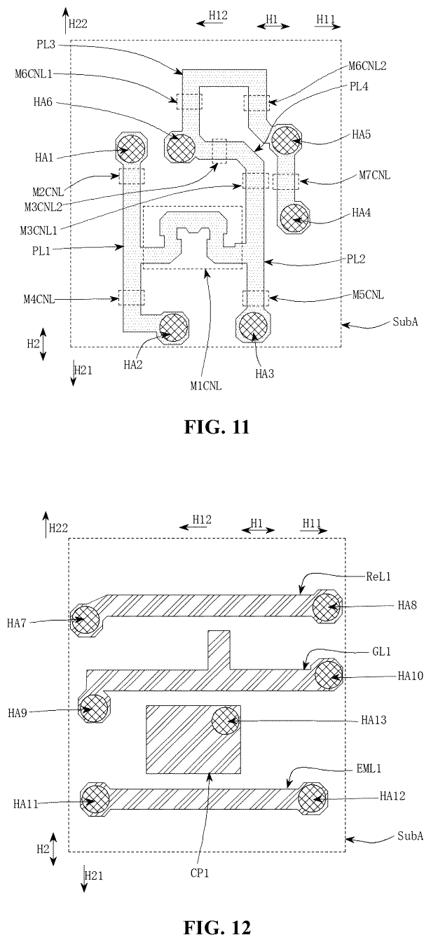

FIG. 11 shows a schematic structural diagram of a polysilicon semiconductor layer in the pixel driving region SubA of the second display region A2. In one pixel driving region SubA, the polysilicon semiconductor layer is provided with an active layer of the driving transistor M1, an active layer of the data writing transistor M2, an active layer of the threshold compensation transistor M3, an active layer of the first light control transistor M4, an active layer of the second light control transistor M5, an active layer of the first reset transistor M6 and an active layer of the second reset transistor M7, and is provided with a first conductive wiring PL1, a second conductive wiring PL2, a third conductive wiring PL3 and a fourth conductive wiring PL4 that are conductorized. In some embodiments, the active layer of any transistor includes a first electrode, a channel region and a second electrode connected in sequence. Herein, the channel region maintains semiconductor properties, while the first electrode, the second electrode, the first conductive wiring PL1, the second conductive wiring PL2, the third conductive wiring PL3, and the fourth conductive wiring PL4 are conductive by doping. FIG. 11 shows a channel region M1CNL of the driving transistor M1, a channel region M2CNL of the data writing transistor M2, a channel region (M3CNL1+M3CNL2) of the threshold compensation transistor M3, a channel region M4CNL of the first light control transistor M4, a channel region M5CNL of the second light control transistor M5, a channel region (M6CNL1+M6CNL2) of the first reset transistor M6, and a channel region M7CNL of the second reset transistor M7.

Referring to FIG. 11, the channel region M2CNL of the data writing transistor M2 and the channel region M4CNL of the first light control transistor M4 are arranged along the column direction H2, and the channel region M4CNL of the first light control transistor M4 and the channel regions M5CNL of the second light control transistor M5 are arranged along the row direction H1. In this disclosure, the row direction H1 includes a first row direction H11 and a second row direction H12 that are opposite. The channel region M5CNL of the second light control transistor M5 is located at the side, in the first row direction H11, of the channel region M4CNL of the first light control transistor M4. The column direction H2 includes a first column direction H21 and a second column direction H22 that are opposite. The channel region M4CNL of the first light control transistor M4 is located at the side, in the first column direction H21, of the channel region M2CNL of the data writing transistor M2.

Referring to FIG. 11, the channel region M2CNL of the data writing transistor M2 and the channel region M4CNL of the first light control transistor M4 are arranged in sequence along the first column direction H21, and the two are electrically connected by the first conductive wiring PL1. The first conductive wiring PL1 extends along the column direction H2, and may also be used as the second electrode of the data writing transistor M2 and the second electrode of the first light control transistor M4. Correspondingly, the first electrode of the data writing transistor M2 is located at the side, in the second column direction H22, of the channel region M2CNL of the data writing transistor M2, and there is a first bottom via region HA1 used for being electrically connected to the data lead DataL through the via hole. The first electrode of the first light control transistor M4 is located at a side, in the first column direction H21, of the channel region M4CNL of the first light control transistor M4, and there is a second bottom via region HA2 used for being electrically connected to the first power voltage lead VDDL through the via hole.

One end of the channel region M1CNL of the driving transistor M1 is connected to the first conductive wiring PL1 and is located at the side, in the first row direction H11, of the first conductive wiring PL1. In this way, the first conductive wiring PL1 may be used as a part of the first node N1 and also used as the first electrode of the driving transistor M1. The other end of the channel region M1CNL of the driving transistor M1 is connected to the second conductive wiring PL2 that is conductorized, so that the second conductive wiring PL2 may be used as a part of the third node N3 and also used as the second electrode of the driving transistor M1. The second conductive wiring PL2 extends in the column direction H2 such that the channel region M1CNL of the driving transistor M1 is sandwiched between the first conductive wiring PL1 and the second conductive wiring PL2.

One end of the second conductive wiring PL2 on the side of the first column direction H21 is connected to the channel region M5CNL of the second light control transistor M5, so that the second conductive wiring PL2 is also used as the first electrode of the second light control transistor M5. The second electrode of the second light control transistor M5 is located at the side, in the first column direction H21, of the channel region M5CNL of the second light control transistor M5, and there is a third bottom via region HA3 used for being electrically connected to the light emitting element C200 through the via hole. One end of the second conductive wiring PL2 on the side of the second column direction H22 is connected to the channel region of the threshold compensation transistor M3, thereby being also used as the second electrode of the threshold compensation transistor M3.

The channel region of the threshold compensation transistor M3 includes a first channel region M3CNL1 of the threshold compensation transistor M3 and a second channel region M3CNL2 of the threshold compensation transistor M3, where the first channel region M3CNL 1 of the threshold compensation transistor M3 and the second channel region M3CNL2 of the threshold compensation transistor M3 are connected through the fourth conductive wiring PL4. In some embodiments, the fourth conductive wiring PL4 is bent, so that the second channel region M3CNL2 of the threshold compensation transistor M3 is disposed at a side, in the second column direction H22, of the first channel region M3CNL1 of the threshold compensation transistor M3. In this way, the gate of the threshold compensation transistor M3 may include a first gate of the threshold compensation transistor M3 overlapping with the first channel region M3CNL1 of the threshold compensation transistor M3 and a second gate of the threshold compensation transistor M3 overlapping with the second channel region M3CNL2 of the threshold compensation transistor M3. The part of the scanning lead GL located in the first gate layer may extend along the row direction H1, and overlap with the first channel region M3CNL1 of the threshold compensation transistor M3 to be also used as the first gate of the threshold compensation transistor M3. The part of the scanning lead GL located in the first gate layer may also be provided with a protrusion extending along the column direction H2, and the protrusion overlaps with the second channel region M3CNL2 of the threshold compensation transistor M3 to be also used as the second gate of the threshold compensation transistor M3. This arrangement can reduce the leakage current of the threshold compensation transistor M3 in the cut-off state, improve the voltage holding capacity of the storage capacitor Cst, and reduce the flicker risk of the display panel PNL when being driven at a low frequency.

The first electrode of the threshold compensation transistor M3 is located at the side, in the second row direction H12, of the second channel region M3CNL2 of the threshold compensation transistor M3, and there is a sixth bottom via region HA6 for being electrically connected to the first electrode plate CP1 of the storage capacitor Cst through a via hole. In this way, the first electrode of the threshold compensation transistor M3 and the first electrode plate CP1 of the storage capacitor Cst may serve as a part of the second node N2.

The channel region of the first reset transistor M6 is located at a side, in the second column direction H22, of the channel region M3CNL of the threshold compensation transistor M3, and includes a first channel region M6CNL1 of the first reset transistor M6 and a second channel region M6CNL2 of the first reset transistor M6. The first channel region M6CNL1 of the first reset transistor M6 and the second channel region M6CNL2 of the first reset transistor M6 are electrically connected through the third conductive wiring PL3. In some embodiments, the first channel region M6CNL 1 of the first reset transistor M6 and the second channel region M6CNL2 of the first reset transistor M6 are sequentially arranged along the first row direction H11. In this way, the reset lead ReL located at the first gate layer may extend along the row direction H1 and overlap with the first channel region M6CNL1 of the first reset transistor M6 and the second channel region M6CNL2 of the first reset transistor M6. The gate of the first reset transistor M6 includes a first gate of the first reset transistor and a second gate of the first reset transistor, where the overlapping portion between the reset lead ReL and the first channel region M6CNL1 of the first reset transistor M6 may also be used as the first gate of the first reset transistor, and the overlapping portion between the reset lead ReL and the second channel region M6CNL2 of the first reset transistor M6 may also be used as the second gate of the first reset transistor. The second electrode of the first reset transistor M6 is also used as the first electrode of the threshold compensation transistor M3, so that the first reset transistor M6 is connected to the second node N2. Since the first reset transistor M6 includes two sub-transistors connected in series, it has a low leakage current in the off state, which can improve the voltage holding capacity of the storage capacitor Cst and reduce the flickering risk of the display panel PNL when being driven at a low frequency.

The first electrode of the first reset transistor M6 is located at a side, in the first row direction H1, of the second electrode of the first reset transistor M6, and may also be used as the first electrode of the second reset transistor M7. The first electrode of the first reset transistor M6 is provided with a fifth bottom via region HA5 for being electrically connected to the initialization lead ViL through a via hole, so that the initialization signal Vinit is loaded to the first electrode of the first reset transistor M6 and the first electrode of the second reset transistor M7.

The channel region M7CNL of the second reset transistor M7 is located at a side, in the first column direction H21, of the first electrode of the second reset transistor M7, and the second electrode of the second reset transistor M7 is located at the side, in the first column direction H21, of the channel region M7CNL of the second reset transistor M7. The second electrode of the second reset transistor M7 is provided with a fourth bottom via region HA4 for being electrically connected to the third bottom via region HA3 through a via hole and other conductive structures.

FIG. 12 is a schematic structural diagram of the first gate layer in the pixel driving region SubA of the second display region A2. Referring to FIG. 12, in the second display region A2, the first gate layer is provided with a first reset sub-lead ReL1, a first scanning sub-lead GL1, a first electrode plate CP1 and a first light control sub-lead EML1 in the pixel driving region SubA, where the first reset sub-lead ReL1, the first scanning sub-lead GL1, the first electrode plate CP1 and the first light control sub-lead EML1 are arranged in sequence along the first column direction H21.

In some embodiments, the first reset sub-lead ReL1 extends along the row direction H1 and sequentially overlaps with the first channel region M6CNL1 of the first reset transistor M6 and the second channel region M6CNL2 of the first reset transistor M6, so as to be also used as the first gate of the first reset transistor M6 and the second gate of the first reset transistor. One end of the first reset sub-lead ReL1 in the second row direction H12 is provided with a seventh bottom via region HA7, one end of the first reset sub-lead ReL1 in the first row direction H11 is provided with an eighth bottom via region HA8, and the seventh bottom via region HA7 and the eighth bottom via region HA8 are used for being electrically connected to the second reset sub-lead ReL2 through via holes.

In some embodiments, the first scanning sub-lead GL1 extends along the row direction H1 and sequentially overlaps with the channel region M2CNL of the data writing transistor M2, the first channel region M3CNL1 of the threshold compensation transistor M3, and the channel region M7CNL of the second reset transistor M7, so as to be also used as the gate of the data writing transistor M2, the first gate of the threshold compensation transistor M3 and the gate of the second reset transistor M7. One end of the first scanning sub-lead GL1 in the second row direction H12 is provided with a ninth bottom via region HA9, one end of the first scanning sub-lead GL1 in the first row direction H11 is provided with a tenth bottom via region HA10, and the ninth bottom via region HA9 and the tenth bottom via region HA10 are used for being electrically connected to the second scanning sub-lead GL2 through a via hole. The first scanning sub-lead GL1 is further provided with a protrusion extending toward the second column direction H22, and the protrusion overlaps with the second channel region M3CNL2 of the threshold compensation transistor M3 to be also used as the second gate of the threshold compensation transistor M3.

In some embodiments, the first light control sub-lead EML1 extends along the row direction H1 and sequentially overlaps with the channel region M4CNL of the first light control transistor M4 and the channel region M5CNL of the second light control transistor M5, so as to be also used as the gate of the first light control transistor M4 and the gate of the second light control transistor M5. One end of the first light control sub-lead EML1 in the second row direction H12 is provided with an eleventh bottom via region HA11, one end of the first light control sub-lead EML1 in the first row direction H11 is provided with a twelfth bottom via region HA12, and the eleventh bottom via region HA11 and the twelfth bottom via region HA12 are used for being electrically connected to the second light control sub-lead EML2 through a via hole.

The first electrode plate CP1 overlaps with the channel region M1CNL of the driving transistor M1, and there is provided with a thirteenth bottom via region HA13 for being electrically connected to the sixth bottom via region HA6 through a via hole or other conductive structures. Further, in the row direction H1, the thirteenth bottom via region HA13 is located at a side, in the first row direction H11, of the first electrode plate CP1; and in the column direction H2, the thirteenth bottom via region HA13 is located at a side, in the second column direction H22, of the first electrode plate CP1.

FIG. 13 is a schematic structural diagram of the second gate layer in the pixel driving region SubA of the second display region A2. Referring to FIG. 13, the second gate layer is provided with a first initialization sub-lead ViL1 and the second electrode plate CP2 in the pixel driving region SubA of the second display region A2, where the first initialization sub-lead ViL1 and the second electrode plate CP2 are arranged sequentially along the first column direction H21.

In some embodiments, two ends of the first initialization sub-lead ViL1 are respectively provided with a fourteenth bottom via region HA14 and a fifteenth bottom via region HA15, and the fourteenth bottom via region HA14 and the fifteenth bottom via region HA15 are respectively used for being electrically connected to the second initialization sub-lead ViL2 through via holes. Furthermore, the fifteenth bottom via region HA15 is located at one end of the first initialization sub-lead ViL1 in the first row direction H11, and is also used for being electrically connected to the fifth bottom via region HA5 through a via hole and other conductive structures. Further, the second initialization sub-lead ViL2 extends along the row direction H1 and at least partially overlaps with the third conductive wiring PL3.

The second electrode plate CP2 overlaps with the first electrode plate CP1, and is provided with a notch that exposes the thirteenth bottom via region HA13, so that the thirteenth bottom via region HA13 can be electrically connected to other conductive structures through the via hole located at the notch. In this example, a side of the second electrode plate CP2 in the second row direction H12 may at least partially overlap with the first conductive wiring PL1, so as to provide electromagnetic shielding for the first conductive wiring PL1 and avoid the coupling effect on the first conductive wiring PL1 caused by transition of the data voltage Data on the data lead DataL. The second electrode plate CP2 may further be provided with an extension extending toward one side of the second column direction H22, where the extension may overlap with the first scanning sub-lead GL1. Referring to FIG. 14, the first source-drain metal layer is provided with a third electrode plate CP3 and a fifth conductive wiring PL5 connected to the third electrode plate CP3. One end of the fifth conductive wiring PL5 in the second column direction H22 is provided with a sixth top via region HB6 connected to the sixth bottom via region HA6 through a via hole. In some embodiments, an orthographic projection of the overlapping portion between the fifth conductive wiring PL5 and the first scanning sub-lead GL1 on the second gate layer may be located within the extension of the third electrode plate CP3. In this way, the extension of the second electrode plate CP2 can shield transition of the scanning signal Gate on the first scanning sub-lead GL1, so as to avoid affecting the gate voltage of driving transistor M1 caused by the transition of the scanning signal Gate coupling to the third electrode plate CP3 (second node N2).

Referring to FIG. 13, the second electrode plate CP2 may be provided with a sixteenth bottom via region HA16 for being electrically connected to the fourth electrode plate CP4 through a via hole.

FIG. 14 shows a schematic structural view of the first source-drain metal layer in the pixel driving region SubA of the second display region A2. Referring to FIG. 14, in the pixel driving region SubA of the second display region A2, the first source-drain metal layer may be provided with a first conductive portion ML1, a second conductive portion ML2, a third conductive portion ML3, a fourth conductive portion ML4, a fifth conductive portion ML5, a sixth conductive portion ML6, a seventh conductive portion ML7, an eighth conductive portion ML8 and a ninth conductive portion ML9, as well as a fifth conductive wiring PL5, a sixth conductive wiring PL6, a seventh conductive wiring PL7, an eighth conductive wiring PL8 and the third electrode plate CP3.

The first conductive portion ML1 overlaps with the fourteenth bottom via region HA14, and is provided with a twenty-sixth bottom via region HA26 and a fourteenth top via region HB14. The fourteenth top via region HB14 is connected to the fourteenth bottom via region HA14 through a via hole. The twenty-sixth bottom via region HA26 is used for being connected to the second initialization sub-lead ViL2 through a via hole. The twenty-sixth bottom via region HA26 and the fourteenth top via region HB14 may partially or completely coincide with each other. One end of the seventh conductive wiring PL7 in the second column direction H22 is provided with a fifteenth top via region HB15 and a twenty-seventh bottom via region HA27, where the fifteenth top via region HB15 is connected to the fifteenth bottom via region HA15 through a via hole, and the twenty-seventh bottom via region HA27 is used for being connected to the second initialization sub-lead ViL2 through a via hole. The fifteenth top via region HB15 and the twenty-seventh bottom via region HA27 may partially or completely coincide with each other. The seventh conductive wiring PL7 extends along the column direction H2, and is provided with a fifth top via region HB5 at one end thereof in the first column direction H21, where the fifth top via region HB5 and the fifth bottom via region HA5 are connected through a via hole. In this way, the second initialization sub-lead ViL2 can be electrically connected to the first initialization sub-lead ViL1 through the first conductive portion ML1 and the seventh conductive wiring PL7, and the initialization signal Vinit loaded on the initialization lead ViL can be loaded to the first electrode of the second reset transistor M7 and the first electrode of the first reset transistor M6.

The second conductive portion ML2 overlaps with the seventh bottom via region HA7, and is provided with a twentieth bottom via region HA20 and a seventh top via region HB7. The seventh top via region HB7 and the seventh bottom via region HA7 are connected through a via hole. The twentieth bottom via region HA20 is used for being connected to the second reset sub-lead ReL2 through a via hole. The twentieth bottom via region HA20 and the seventh top via region HB7 may partially or completely coincide with each other. The eighth conductive portion ML8 overlaps with the eighth bottom via region HA8, and is provided with an eighth top via region HB8 and a twenty-first bottom via region HA21, where the eighth top via region HB8 and the eighth bottom via region HA8 are connected through a via hole, and the twenty-first bottom via region HA21 is used for being connected to the second reset sub-lead ReL2 through a via hole. The eighth top via region HB8 and the twenty-first bottom via region HA21 may partially or completely coincide with each other. In this way, the second reset sub-lead ReL2 can be electrically connected to the first reset sub-lead ReL1 through the second conductive portion ML2 and the eighth conductive portion ML8.

The third conductive portion ML3 overlaps with the first bottom via region HA1, and has an eighteenth bottom via region HA18 and a first top via region HB1. The first top via region HB1 is connected to the first bottom via region HA1 through a via hole. The eighteenth bottom via region HA18 is configured to electrically connect with the data lead DataL through the via hole. The eighteenth bottom via region HA18 and the first top via region HB1 may partially or completely overlap. In this way, the data line DataL may be connected to the first electrode of the data writing transistor M2 through the third conductive portion ML3, so that the data voltage Data applied on the data line DataL is applied to the first electrode of the data writing transistor M2.

The ninth conductive portion ML9 overlaps with the ninth bottom via region HA9, and is provided with a twenty-second bottom via region HA22 and a ninth top via region HB9. The ninth top via region HB9 and the ninth bottom via region HA9 are connected through a via hole. The twenty-second bottom via region HA22 is used for being connected to the second scanning sub-lead GL2 through a via hole. The twenty-second bottom via region HA22 and the ninth top via region HB9 may partially or completely coincide with each other. The seventh conductive portion ML7 overlaps with the tenth bottom via region HA10, and is provided with a tenth top via region HB10 and a twenty-third bottom via region HA23, where the tenth top via region HB10 and the tenth bottom via region HA10 are connected through a via hole, and the twenty-third bottom via region HA23 is used for being connected to the second scanning sub-lead GL2 through a via hole. The tenth top via region HB10 and the tenth bottom via region HA10 may partially or completely coincide with each other. In this way, the second scanning sub-lead GL2 can be electrically connected to the first scanning sub-lead GL1 through the seventh conductive portion ML7 and the ninth conductive portion ML9.

The fifth conductive portion ML5 overlaps with the eleventh bottom via region HA11, and is provided with a twenty-fourth bottom via region HA24 and an eleventh top via region HB11. The eleventh top via region HB11 and the eleventh bottom via region HA11 are connected through a via hole. The twenty-fourth bottom via region HA24 is used for being connected to the second light control sub-lead EML2 through a via hole. The twenty-fourth bottom via region HA24 and the eleventh top via region HB11 may partially or completely coincide with each other. The sixth conductive portion ML6 overlaps with the twelfth bottom via region HA12, and is provided with a twelfth top via region HB12 and a twenty-fifth bottom via region HA25, where the twelfth top via region HB12 and the twelfth bottom via region HA12 are connected through a via hole, and the twenty-fifth bottom via region HA25 is used for being connected to the second light control sub-lead EML2 through a via hole. The twelfth top via region HB12 and the twenty-fifth bottom via region HA25 may partially or completely coincide with each other. In this way, the second light control sub-lead EML2 can be electrically connected to the first light control sub-lead EML1 through the fifth conductive portion ML5 and the sixth conductive portion ML6.

The fourth conductive portion ML4 overlaps with the second electrode plate CP2 and is connected to the sixth conductive wiring PL6. In some embodiments, the fourth conductive portion ML4 is provided with a seventeenth bottom via region HA17 and a sixteenth top via region HB16, and the sixteenth top via region HB16 and the sixteenth bottom via region HA16 are connected through a via hole. The seventeenth bottom via region HA17 is used for being electrically connected to the first power voltage lead VDDL through a via hole. In some embodiments, the seventeenth bottom via region HA17 and the sixteenth top via region HB16 do not intersect. The sixth conductive wiring PL6 is connected to the fourth conductive portion ML4 and is located at a side of the fourth conductive portion ML4 in the first column direction H21. One end of the sixth conductive wiring PL6 in the first column direction H21 is provided with a second top via region HB2, and the second top via region HB2 is connected to the second bottom via region HA2 through a via hole. In this way, the first electrode of the first light control transistor M4 is electrically connected to the first power voltage lead VDDL through the sixth conductive wiring PL6 and the fourth conductive portion ML4, so that the first power voltage VDD can be applied to the first electrode of the first light control transistor M4 and the second electrode plate CP2.

The third electrode plate CP3 overlaps with the second electrode plate CP2, and is provided with a thirteenth top via region HB13 overlapping with the thirteenth bottom via region HA13, where the thirteenth top via region HB13 is connected to the thirteenth bottom via region HA13 through a via hole. In this way, the first electrode plate CP1 and the third electrode plate CP3 are connected as a part of the second node N2. The fifth conductive wiring PL5 is connected to the third electrode plate CP3 and extends toward the second column direction H22. One end of the fifth conductive wiring PL5 in the second column direction H22 is provided with a sixth top via region HB6 overlapping with the sixth bottom via region HA6, and the sixth top via region HB6 and the sixth bottom via region HA6 are connected through a via hole. In this way, the third electrode plate CP3 is connected to the second electrode of the first reset transistor M6 and the first electrode of the threshold compensation transistor M3 through the fifth conductive wiring PL5.

Two ends of the eighth conductive wiring PL8 are respectively provided with a fourth top via region HB4 overlapping with the fourth bottom via region HA4 and a third top via region HB3 overlapping with the third bottom via region HA3, where the fourth top via region HB4 is connected to the fourth bottom via region HA4 through a via hole, and the third top via region HB3 is connected to the third bottom via region HA3 through a via hole. In this way, the second electrode of the second reset transistor M7 is connected to the second electrode of the second light control transistor M5 through the eighth conductive wiring PL8. The eighth conductive wiring PL8 is further provided with a first bottom via region HA19 close to the third top via region HB3, and the first bottom via region HA19 is used for being electrically connected to the light emitting element C200 through a via hole. Further, the first bottom via region HA19 and the third top via region HB3 may partially or completely coincide with each other.

FIG. 15 and FIG. 16 show schematic structural diagrams of the transparent wiring layer in the second display region A2. It can be understood that, in the second display region A2, there may be certain differences in the wiring of the transparent wiring layer at different positions, as long as the required signal can be loaded to the pixel driving circuit.

Referring to FIG. 7, FIG. 15 and FIG. 16, the transparent wiring layer is provided with a second initialization sub-lead ViL2, a second reset sub-lead ReL2, a second scanning sub-lead GL2, a second light control sub-lead EML2, a data lead DataL, and a second power sub-lead VDDL2 and so on in the second display region A2.

One end of the second initialization sub-lead ViL2, one end of the second reset sub-lead ReL2, one end of the second scanning sub-lead GL2 and one end of the second light control sub-lead EML2 extend into the pixel driving region SubA of the second display region A2, and are respectively connected to a corresponding wiring in the first source-drain metal layer through a via hole.

Referring to FIG. 7, FIG. 9, FIG. 14, FIG. 15 and FIG. 16, in the pixel driving region SubA of the second display region A2, the second initialization sub-lead on a side, in the second row direction H12, of the first initialization sub-lead ViL1 has its one end in the first row direction H11 being provided with a twenty-sixth top via region HB26 overlapping with the twenty-sixth bottom via region HA26. The twenty-sixth top via region HB26 is connected to the twenty-sixth bottom via region HA26 through a via hole, such that the second initialization sub-lead ViL2 can be electrically connected to the first initialization sub-lead ViL1. The second initialization sub-lead ViL2 on a side, in the first row direction H11, of the first initialization sub-lead ViL1 has its one end in the second row direction H12 being provided with a twenty-seventh top via region HB27 overlapping with the twenty-seventh bottom via region HA27. The twenty-seventh top via region HB27 is connected to the twenty-seventh bottom via region HA27 through a via hole, such that the second initialization sub-lead ViL2 can be electrically connected to the first initialization sub-lead ViL1. In this way, in the second display region A2, the second initialization sub-leads ViL2 and the first initialization sub-leads ViL1 are arranged alternately and connected in sequence to form the initialization lead ViL.

Referring to FIG. 7, FIG. 8, FIG. 14, FIG. 15 and FIG. 16, in a pixel drive region SubA of the second display region A2, the second reset sub-lead ReL2 at a side, in the second row direction H12, of the first reset sub-lead ReL1 has its one end in the first row direction H11 being provided with a twentieth top via region HB20 overlapping with the twentieth bottom via region HA20. The twentieth top via region HB20 and the twentieth bottom via region HA20 are connected through a via hole, such that the second reset sub-lead ReL2 can be electrically connected to the first reset sub-lead ReL1. The second reset sub-lead ReL2 at a side, in the first row direction H11, of the first reset sub-lead ReL1 has its one end in the second row direction H12 being provided with a twenty-first top via region HB21 overlapping with the twenty-first bottom via region HA21. The twenty-first top via region HB21 and the twenty-first bottom via region HA21 are connected through a via hole, such that the second reset sub-lead ReL2 can be electrically connected to the first reset sub-lead ReL1. In this way, in the second display region A2, the second reset sub-leads ReL2 and the first reset sub-leads ReL1 are alternately arranged and connected in sequence to form the reset lead ReL.

Referring to FIG. 7, FIG. 8, FIG. 14, FIG. 15 and FIG. 16, in a pixel driving region SubA of the second display region A2, the second scanning sub-lead GL2, on a side, in the second row direction H12, of the first scanning sub-lead GL1 has its one end in the first row direction H11 being provided with a twenty-second top via region HB22 overlapping with the twenty-second bottom via region HA22. The twenty-second top via region HB22 and the twenty-second bottom via region HA22 are connected through a via hole, such that the second scanning sub-lead GL2 can be electrically connected to the first scanning sub-lead GL1. The second scanning sub-lead GL2 on a side, in the first row direction H11, of the first scanning sub-lead GL1 has its one end in the second row direction H12 being provided with a twenty-third top via region HB23 overlapping with the twenty-third bottom via region HA23. The twenty-third top via region HB23 is connected to the twenty-third bottom via region HA23 are connected through a via hole, such that the second scanning sub-lead GL2 can be electrically connected to the first scanning sub-lead GL1. In this way, in the second display region A2, the second scanning sub-leads GL2 and the first scanning sub-leads GL1 are alternately arranged and connected in sequence to form the scanning lead GL.

Referring to FIG. 7, FIG. 8, FIG. 14, FIG. 15 and FIG. 16, in a pixel drive region SubA of the second display region A2, the second light control sub-lead EML2 on a side, in the second row direction H12, of the first light control sub-lead EML1 has its one end in the first row direction H11 being provided with a twenty-fourth top via region HB24 overlapping with the twenty-fourth bottom via region HA24. The twenty-fourth top via region HB24 and the twenty-fourth bottom via region HA24 are connected through a via hole, such that the second light control sub-lead EML2 can be electrically connected to the first light control sub-lead EML1. The second light control sub-lead EML2 at a side, in the first row direction H11, of the first light control sub-lead EML1 has its one end in the second row direction H12 being provided with a twenty-fifth top via region HB25 overlapping with the twenty-fifth bottom via region HA25. The twenty-fifth top via region HB25 is connected to the twenty-fifth bottom via region HA25 through a via hole, such that the second light control sub-lead EML2 can be electrically connected to the first light control sub-lead EML1. In this way, in the second display region A2, the second light control sub-leads EML2 and the first light control sub-leads EML1 are alternately arranged and connected in sequence to form the light control lead EML.

Referring to FIG. 10, FIG. 15, FIG. 16, and FIG. 17, one end of the second power sub-lead VDDL2 extends into the pixel driving region SubA of the second display region A2, and is connected to the first power sub-lead VDDL1 in the second source-drain metal layer through a via hole.

In some embodiments, the second power sub-lead VDDL2 on a side, in the second column direction H22, of a pixel driving region SubA in the second display region A2 is provided with a twenty-ninth bottom via region HA29 has its one end in the first column direction H21 being provided with a twenty-ninth bottom via region HA29 used for being connected to the first power sub-lead VDDL1 located in the second source-drain metal layer through a via hole. The second power sub-lead VDDL2 on a side, in the first column direction H21, of the pixel driving region SubA has its one end being provided with a twenty-eighth bottom via region HA28 for being connected to the first power sub-lead VDDL1 located in the second source-drain metal layer. Furthermore, the second power sub-lead VDDL2 located on the side, in the first column direction H21, of the pixel driving region SubA has its one end in the second column direction H22 being provided with a seventeenth top via region HB17 overlapping with the seventeenth bottom via region HA17. The seventeenth top via region HB17 and the seventeenth bottom via region HA17 are connected through a via hole.

Referring to FIG. 10, FIG. 15 and FIG. 16, in the second display region A2, the data lead DataL is located in the transparent wiring layer and passes through the pixel driving region SubA along the column direction H2. In some embodiments, the data lead DataL is provided with an eighteenth top via region HB18 overlapping with the eighteenth bottom via region HA18, and the eighteenth top via region HB18 is connected to the eighteenth bottom via region HA18 through a via hole.

FIG. 17 shows a schematic structural diagram of the second source-drain metal layer in a pixel driving region SubA of the second display region A2. Referring to FIG. 17, the second source-drain metal layer includes, in the pixel driving region SubA of the second display region A2, a tenth conductive portion ML10, an eleventh conductive portion ML11 and a first power sub-lead VDDL1. In some embodiments, the eleventh conductive portion ML11 covers the eighteenth top via region HB18, so as to shield the interference of external signals on the data voltage Data. The tenth conductive portion ML10 is provided with a thirtieth top via region HB30 overlapping with the thirtieth bottom via region HA30, and the thirtieth top via region HB30 is connected to the thirtieth bottom via region HA30 through a via hole. The pixel electrode of the light emitting element C200 may be connected to the tenth conductive portion ML 10 through a via hole.

The first power sub-lead VDDL1 extends along the column direction H2, and has its both ends being respectively provided with a twenty-ninth top via region HB29 overlapping with the twenty-ninth bottom via region HA29, and a twenty-eighth top via region HB28 overlapping with the twenty-eighth bottom via region HA28. In some embodiments, the twenty-eighth top via region HB28 is connected to the twenty-eighth bottom via region HA28 through a via hole, and the twenty-ninth top via region HB29 is connected to the twenty-ninth bottom via region HA29 through a via hole.

Other embodiments of this disclosure will be readily apparent to those skilled in the art from consideration of the specification and practice of the invention disclosed herein. This application is intended to cover any modification, use or adaptation of this disclosure, and these modifications, uses or adaptations follow the general principles of this disclosure and include common knowledge or conventional technical means in the art not disclosed in this disclosure. The specification and examples are to be considered exemplary only, with the true scope and spirit of the disclosure indicated by the appended claims.

1. A display panel, comprising a display region and a peripheral region surrounding the display region; wherein a binding region is provided on a side of the peripheral region; the display region comprises a first display region and a second display region adjacent to each other; a light transmittance of the second display region is greater than a light transmittance of the first display region;
the display panel further comprises a plurality of pixel driving circuits and data leads for loading data voltages to the pixel driving circuits; and
in the second display region, capacitance values change gradually in storage capacitors of respective ones of the pixel driving circuits sequentially connected to a same one of the data leads.

2. The display panel according to claim 1,
wherein, along a direction away from the binding region, the capacitance values decrease gradually in the storage capacitors of the respective ones of the pixel driving circuits located in the second display region and connected to the same one of the data leads.

3. The display panel according to claim 1, wherein the display panel further comprises scanning leads for loading scanning signals to the pixel driving circuits; and
in the second display region, capacitance values are the same in storage capacitors of respective ones of the pixel driving circuits sequentially connected to a same one of the scanning leads.

4. The display panel according to claim 1, wherein a storage capacitor of the pixel driving circuit comprises multi-layer electrode plates sequentially stacked on a side of a base substrate of the display panel;
odd-numbered layers of the electrode plates are electrically connected to each other, and even-numbered layers of the electrode plates are electrically connected to each other; two adjacent layers of the electrode plates overlap and are electrically insulated with each other; a total overlapping area of the electrode plates of the storage capacitor is equal to a sum of overlapping areas between any two adjacent layers of the electrode plates; and
along a direction away from the binding area, the total overlapping areas of the electrode plates decrease gradually in the storage capacitors of the respective ones of the pixel driving circuits located in the second display region and connected to the same one of the data leads.

5. The display panel according to claim 4, wherein, in the second display region, a number of electrode plates of the storage capacitor of the pixel driving circuit is four.

6. The display panel according to claim 5, wherein an overlapping area between a first electrode plate and a second electrode plate is a first overlapping area; an overlapping area between the second electrode plate and a third electrode plate is a second overlapping area; an overlapping area between the third electrode plate and a fourth electrode plate is a third overlapping area; and
along the direction away from the binding region, at least one of the first overlapping areas, the second overlapping areas and the third overlapping areas decrease gradually in the storage capacitors of the respective ones of the pixel driving circuits located in the second display region and connected to the same one of the data leads.

7. The display panel according to claim 5, wherein the pixel driving circuit comprises a driving transistor for generating a driving current; a first electrode plate of the storage capacitor is reused as a gate of the driving transistor; and
along the direction away from the binding region, areas of the first electrode plates remain unchanged in the storage capacitors of the respective ones of the pixel driving circuits located in the second display region and connected to the same one of the data leads.

8. The display panel according to claim 1, wherein the display panel further comprises pixel driving regions for providing the pixel driving circuits; and
an area of a pixel driving region in the second display region is smaller than an area of a pixel driving region in the first display region.

9. The display panel according to claim 8, wherein the display panel further comprises signal lines for connecting adjacent ones of the pixel driving circuits; and
in the second display region, a material of a part of the signal lines outside the pixel driving region is a transparent conductive material.

10. The display panel according to claim 8, wherein the display panel further comprises a base substrate, a semiconductor layer, a first gate layer, a second gate layer, a first source-drain metal layer, a second source-drain metal layer and a pixel electrode layer sequentially stacked; the display panel further comprises a transparent wiring layer located between any two adjacent ones of the semiconductor layer, the first gate layer, the second gate layer, the first source-drain metal layer, the second source-drain metal layer and the pixel electrode layer; and
in the second display region, a part of the signal lines outside the pixel driving region is located in the transparent wiring layer.

11. A display panel, comprising a base substrate, a driving circuit layer, and a pixel layer stacked in sequence; wherein,
the pixel layer is provided with sub-pixels, the driving circuit layer is provided with pixel driving circuits for driving the sub-pixels, and the driving circuit layer comprises a thin film transistor and a storage capacitor; and
the storage capacitor comprises multi-layer electrode plates stacked in sequence; odd-numbered layers of the electrode plates are electrically connected to each other, and even-numbered layers of the electrode plates are electrically connected to each other; two adjacent layers of the electrode plates overlap and are electrically insulated with each other; and at least part of the storage capacitors comprises more than two layers of the electrode plates.

12. The display panel according to claim 11, wherein at least part of the storage capacitors comprises four layers of the electrode plates; or
wherein at least part of the storage capacitors comprises two layers of the electrode plates.

13. (canceled)

14. The display panel according to claim 11, further comprising a display region and a peripheral region surrounding the display region; wherein the display region comprises a first display region and a second display region adjacent to each other; a light transmittance of the second display region is greater than a light transmittance of the first display region;
the first display region is provided with a first pixel driving circuit, and the second display region is provided with a second pixel driving circuit.

15. The display panel according to claim 14, wherein a storage capacitor of the first pixel driving circuit comprises two layers of electrode plates; or
wherein a storage capacitor of the second pixel driving circuit comprises four layers of electrode plates.

16. (canceled)

17. The display panel according to claim 14, further comprising a first pixel driving region for providing the first pixel driving circuit and a second pixel driving region for providing the second pixel driving circuit;
wherein an area of the second pixel driving region is smaller than an area of the first pixel driving region.

18. The display panel according to claim 17, further comprising signal lines for connecting adjacent ones of the pixel driving circuits; and
in the second display region, a material of a part of the signal lines outside the second pixel driving region is a transparent conductive material.

19. The display panel according to claim 18, further comprising a base substrate, a semiconductor layer, a first gate layer, a second gate layer, a first source-drain metal layer, a second source-drain metal layer and a pixel electrode layer sequentially stacked; wherein the display panel further comprises a transparent wiring layer located between any two adjacent ones of the semiconductor layer, the first gate layer, the second gate layer, the first source-drain metal layer, the second source-drain metal layer and the pixel electrode layer; and
in the second display region, a part of the signal lines outside the second pixel driving region is located in the transparent wiring layer.

20. The display panel according to claim 11, wherein the driving circuit layer comprises a semiconductor layer, a first gate insulating layer, a first gate layer, a second gate insulating layer, a second gate layer, an interlayer dielectric layer, a first source-drain metal layer, a first planarization layer, a second source-drain metal layer and a second planarization layer sequentially stacked on a side of the base substrate; the driving circuit layer further comprises a transparent wiring layer located between any two adjacent ones of the semiconductor layer, the first gate layer, the second gate layer, the first source-drain metal layer, the second source-drain metal layer and the pixel electrode layer; and
the multi-layer electrode plates of the storage capacitor are respectively located in multiple ones of the first gate layer, the second gate layer, the first source-drain metal layer, the second source-drain metal layer and the transparent wiring layer.

21. The display panel according to claim 11, wherein the driving circuit layer comprises a semiconductor layer, a first gate insulating layer, a first gate layer, a second gate insulating layer, a second gate layer, an interlayer dielectric layer, a first source-drain metal layer, a first planarization layer, a second source-drain metal layer and a second planarization layer sequentially stacked on a side of the base substrate; and
the multi-layer electrode plates of the storage capacitor are respectively located in multiple ones of the first gate layer, the second gate layer, the first source-drain metal layer and the second source-drain metal layer.

22. A display device, comprising a display panel comprising a base substrate, a driving layer, a pixel layer and a touch layer stacked sequentially; wherein, in a peripheral area of the display panel, the driving layer is provided with a touch pin and a touch relay wire connected with the touch pin; the touch layer comprises a touch organic layer and a touch metal layer buried in the touch organic layer, and the touch metal layer is formed with a touch channel and a touch wiring connected with the touch channel;
wherein, the touch organic layer exposes the touch pin, and an end of the touch relay wire away from the touch pin extends between the touch organic layer and the base substrate;
the touch wiring does not protrude out of the touch organic layer, and the touch wiring is electrically connected to the end of the touch relay wire away from the touch pin through a via hole.
